(19) United States
(12) Patent Application Publication
(10) Pub. No.: US 2026/0276559 A1
(43) Pub. Date: Sep. 17, 2026

(54) Inspection Method, Inspection Device, and Substrate Processing Device

(71) Applicant: Tokyo Electron Limited, Tokyo (JP)

(72) Inventors: Hirokazu UEDA, Osaka (JP); Yasutoshi UMEHARA, Tokyo (JP); Hiroyuki KOISHI, Tokyo (JP)

(21) Appl. No.: 19/676,631

(22) Filed: May 13, 2026

Related U.S. Application Data
(63) Continuation of application No. PCT/JP2024/041389, filed on Nov. 22, 2024.

(30) Foreign Application Priority Data
Nov. 24, 2023 (JP) 2023-199292
Nov. 21, 2024 (JP) 2024-203435

(51) Int. Cl. G01N 21/95; G01N 21/55; G01N 21/88; G01N 21/956

(52) U.S. Cl. CPC G01N 21/9501; G01N 21/55; G01N 21/8851; G01N 21/95607; G01N 21/95684; G01N 2021/95615; G01N 2201/1293

(57) ABSTRACT

A method for inspecting a substrate comprises measuring a characteristic spectrum indicating light absorption or reflection with respect to wavelength of light by irradiating a measurement area on the substrate with light. An arrangement state of the substrate in the measurement area is determined from a structure of the substrate identified by comparing an inspection target spectrum, which is the measured characteristic spectrum, with a reference spectrum. The reference spectrum is obtained from a training model based on a film thickness or a substrate thickness identified from the substrate. The training model is generated by learning characteristic spectra for a plurality of substrates in association with the film thickness of a film formed on a surface of the substrate or the substrate thickness, in a case where the characteristic spectrum changes according to the structure of the substrate in the measurement area.

### CROSS-REFERENCE TO RELATED APPLICATIONS

This application is a bypass continuation application of International Application No. PCT/JP2024/041389 having an international filing date of Nov. 22, 2024 and designating the United States, the International Application being based upon and claiming the benefit of priority from Japanese Patent Application No. 2023-199292 filed on Nov. 24, 2023 and Japanese Patent Application No. 2024-203435 filed on Nov. 21, 2024, the entire contents of which are incorporated herein by reference.

### TECHNICAL FIELD

The present disclosure relates to an inspection method, an inspection device, and a substrate processing apparatus.

### BACKGROUND

In a substrate processing apparatus, after a film is formed on a substrate such as a wafer, inspection may be performed to determine whether or not the film has a preset film thickness or whether or not abnormalities such as voids exist in the film. Japanese Laid-Open Patent Publication No. 2007-56336 discloses evaluation of a thin film by irradiating a wafer with laser light in a film thickness measurement part for measuring a film thickness of a thin film and analyzing light reflected from the wafer using spectroscopic ellipsometry.

### SUMMARY

The present disclosure provides a technology capable of determining an arrangement state of a substrate based on a spectrum indicating absorption or reflection characteristics obtained by irradiating light onto the substrate.

According to an exemplary embodiment, a method for inspecting a substrate by irradiating a substrate with light is provided. The method for inspecting a substrate by irradiating a substrate with light, comprising: irradiating a measurement area set on the substrate with light and measuring a characteristic spectrum indicating characteristics of light absorption or reflection with respect to a wavelength of the light; and determining an arrangement state of the substrate in the measurement area from a structure of the substrate identified by comparing an inspection target spectrum, which is the characteristic spectrum measured in said measuring the characteristic spectrum, with a reference spectrum, which is the characteristic spectrum obtained from a training model based on a film thickness or a substrate thickness identified from the substrate from which the inspection target spectrum was acquired, using the training model generated by learning the characteristic spectrum for multiple substrates in association with the film thickness when a film is formed on a surface of the substrate or a substrate thickness in a case where the characteristic spectrum changes according to the structure of the substrate in the measurement area.

### BRIEF DESCRIPTION OF THE DRAWINGS

FIG. 1 is a structural diagram showing an inspection apparatus according to a first embodiment.

FIG. 2 is a configuration diagram showing a control device in the first embodiment.

FIG. 3 is a partial plan view showing positioning of a measurement area in a comparative embodiment.

FIGS. 4A to 4D are longitudinal side views of a substrate W, showing a process of moving a measurement area to an inspection area.

FIG. 5 is a graph illustrating reflectance spectra in FIGS. 4A to 4C.

FIG. 6 is a graph showing changes in a wavelength of a singular point with respect to a film thickness of a SiN film.

FIG. 7 is a partial plan view showing the positioning of a measurement area in the first embodiment.

FIG. 8 is a flowchart showing a generation operation.

FIG. 9 is a flowchart showing a determination operation and a movement operation.

FIG. 10 is a longitudinal side view illustrating a substrate having another film.

FIG. 11 is a graph showing reflectance spectra at measurement positions shown in FIG. 10.

FIG. 12 is a longitudinal side view illustrating a substrate in which tapered portions are formed.

FIG. 13 is a graph showing reflectance spectra at measurement positions shown in FIG. 12.

FIG. 14 is a partial plan view showing positioning in a modification of the first embodiment.

FIG. 15 is a flowchart showing a generation operation of the modification.

FIG. 16 is a flowchart showing a determination operation and a movement operation of the modification.

FIG. 17 is a plan view showing a film forming system.

FIG. 18 is a longitudinal side view showing a film forming module.

FIG. 19A is a plan view showing a state in which a measurement area is positioned at an alignment mark in a second embodiment.

FIG. 19B is a plan view showing a state in which the measurement area is shifted from the alignment mark in the second embodiment.

FIG. 20 is a longitudinal side view illustrating positioning to the alignment mark.

FIG. 21 is a longitudinal side view showing an upper substrate and a lower substrate before bonding.

FIG. 22 is a longitudinal side view showing an upper substrate and a lower substrate bonded in an aligned state.

FIG. 23 is a longitudinal side view showing an upper substrate and a lower substrate bonded in a misaligned state.

FIG. 24 is a longitudinal side view showing a bonding device.

FIG. 25 is a structural diagram showing an inspection apparatus according to a fourth embodiment.

FIG. 26 is an explanatory diagram showing the principle of spectroscopic measurement by a hyperspectral camera (HSC).

FIG. 27 is a partial plan view showing a measurement area where spectroscopic measurement of the fourth embodiment is performed.

FIG. 28 is a graph showing a characteristic spectrum by the spectroscopic measurement of the fourth embodiment.

FIG. 29 is a graph showing reflectance spectra in the case of performing spectroscopic measurement at different illuminance levels.

FIG. 30 is a longitudinal side view showing an example of a film forming module provided with an inspection apparatus using HSC.

FIG. 31 is a transverse plan view showing the film forming module.

FIG. 32 is a reflectance spectrum showing the results of Test 1.

FIG. 33 is a table summarizing the conditions of spectroscopic measurement in Test 2.

FIG. 34 is a first graph showing the results of Test 2.

FIG. 35 is a second graph showing the results of Test 2.

FIG. 36 is an upper perspective view showing a rotary table on which a substrate to be subjected to spectroscopic measurement in Test 3 is placed.

FIG. 37 is a first graph showing the test results of Test 3.

FIG. 38 is a second graph showing the test results of Test 3.

### DETAILED DESCRIPTION

### First Embodiment

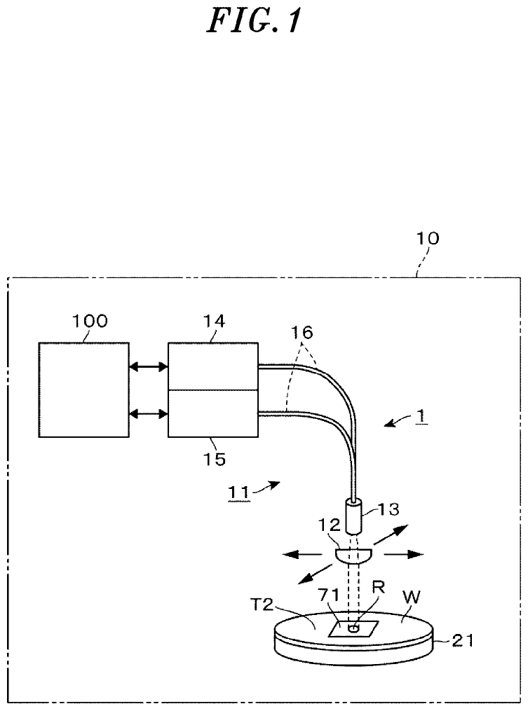

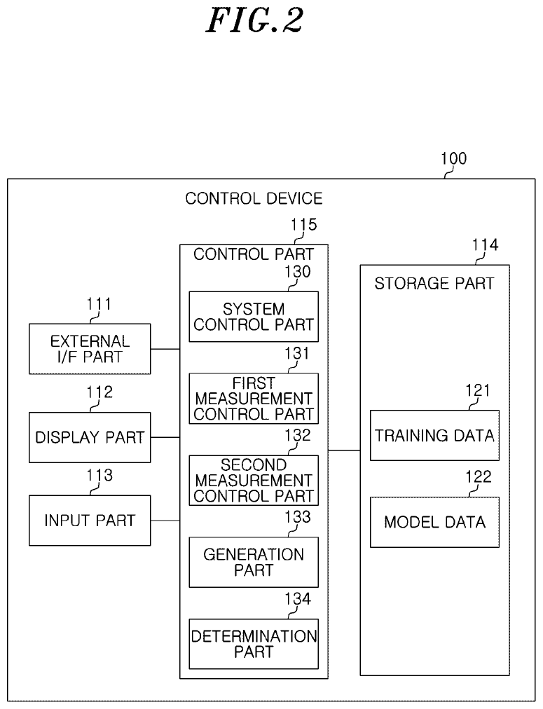

Hereinafter, an inspection apparatus 1 according to a first embodiment will be described in detail with reference to the accompanying drawings. The inspection apparatus 1 according to the first embodiment has a function of guiding measurement light for performing spectroscopic measurement of a substrate W to a correct irradiation position. FIG. 1 is a structural diagram showing the inspection apparatus 1 according to the present embodiment. FIG. 2 is a configuration diagram showing a control device 100 in the present embodiment. In the present embodiment, the inspection apparatus 1 is located in a film forming system 10 that performs film formation to be described later, for example, and performs inspection of the substrate W that has been subjected to film formation, together with the control device 100 that controls the film formation of the film forming system 10.

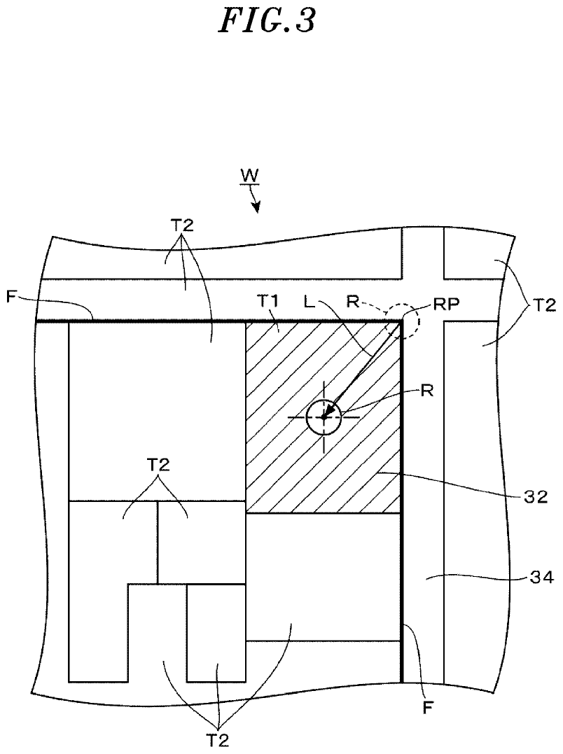

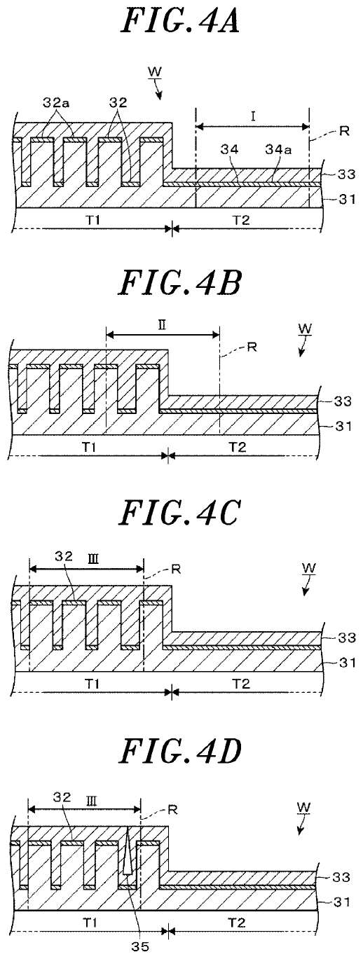

As illustrated in the plan view of FIG. 3 and the longitudinal side view of FIG. 4A, in the substrate W to be inspected, an underlying layer 31 constituting a surface of a semiconductor wafer has an uneven pattern 32 formed by etching or the like. A surface film 33 is formed on the uneven pattern 32 by film formation in the film forming system 10. The diagonal lines in an inspection area T1 in FIG. 3 schematically represent the uneven pattern 32. The underlying layer 31 is made of, e.g., silicon (Si) constituting the substrate W. The surface film 33 is, e.g., a silicon nitride (SiN) film or a silicon oxide (SiO₂) film. The inspection apparatus 1 performs, e.g., film thickness inspection that measures the film thickness of the surface film 33 and determines whether or not the film thickness is within a preset range. The film thickness inspection is performed on the inspection area T1 where the surface film 33 is formed on the uneven pattern 32, and inspects whether or not the surface film 33 is formed to have an appropriate thickness without voids, for example.

As shown in FIG. 1, the inspection apparatus 1 includes a measurement part (inspection part) 11 for performing spectroscopic measurement, a stage 21 on which the substrate W is placed, and a control device 100. The inspection apparatus 1 irradiates the inspection area T1 of the substrate W on the stage 21 with measurement light and performs the film thickness inspection of the surface film 33 by an optical method using reflected light to be described later. As will be described later, when the irradiation of the measurement light and the reception of the reflected light are performed from a common position, the measurement area R for the film thickness inspection is an area on the substrate W irradiated with the measurement light, and is a range where the reflected light from the substrate W can be detected. Further, the measurement area R is an area where the spectroscopic measurement for the film thickness inspection is effectively performed on the substrate W, and accurate film thickness measurement cannot be performed unless the entire range is located within the inspection area T1. In other words, it is necessary to irradiate the measurement light such that the measurement area R does not include a non-inspection area T2 adjacent to the inspection area T1. Otherwise, when data indicating a film thickness outside an allowable range is obtained in the film thickness inspection, it is difficult to determine whether this is due to a defect in the surface film or due to a positional deviation of the measurement area R, and accurate inspection results cannot be obtained. Therefore, the inspection apparatus 1 performs positioning in advance to locate the measurement area R in the inspection area T1 prior to the film thickness inspection.

Hereinafter, “the entire range of the measurement area R is located in the inspection area T1” may be referred to as “the measurement area R is appropriately located in the inspection area T1”, for example. Further, “at least a part of the measurement area R is not located in the inspection area T1,” in which case accurate inspection results are not output, may be referred to as “the measurement area R is not appropriately located in the inspection area T1”, for example.

The measurement part 11 of the inspection apparatus 1 includes a collimator lens 12, a coaxial probe 13 that irradiates measurement light and receives reflected light through the collimator lens 12, an irradiator 14, and a measuring device 15 for spectroscopic measurement. The measurement part 11 includes a moving mechanism (not shown) that displaces the positions of the collimator lens 12 and the coaxial probe 13. The distance in the height direction of the coaxial probe 13 and the collimator lens 12 relative to the substrate W is adjusted such that the measurement area R can be located without extending beyond the inspection area T1.

The irradiator 14 incorporates a light source for emitting measurement light in a wavelength range from visible light to ultraviolet light used for positioning the measurement area R, and optical elements such as mirrors and lenses. The coaxial probe 13 includes a central part for irradiating light and an outer peripheral part for receiving light. The central part is connected to the irradiator 14, and the outer peripheral part is connected to the measuring device 15 via optical fibers 16. The measurement light irradiated from the coaxial probe 13 irradiates the measurement area R, which is at least a part of the inspection area T1 to be subjected to film thickness inspection on the substrate W, and the measuring device 15 detects the light reflected from the measurement area R via the outer peripheral part of the coaxial probe 13 and the optical fibers 16.

FIG. 2 is a diagram showing an example of a schematic configuration of the control device 100 according to the present embodiment. The control device 100 is an information processing device, e.g., a computer or the like. The control device 100 has an external interface (I/F) part 111, a display part 112, an input part 113, a storage part 114, and a control part 115. The control device 100 may have various functional parts of a known computer in addition to the functional parts shown in FIG. 2.

The external I/F part 111 is an interface for inputting and outputting information to and from other devices. For example, the external I/F part 111 is an interface that performs communication control with other devices. As one aspect of the external I/F part 111, a network interface card such as a LAN card can be adopted. For example, the external I/F part 111 transmits and receives various types of data to and from the film forming system 10 or other devices via a network. Further, the external I/F part 111 may be an interface such as a Universal Serial Bus (USB) port.

The display part 112 is a display device that displays various types of information. The display part 112 may be display devices such as a liquid crystal display (LCD), a cathode ray tube (CRT) and the like. The display part 112 displays various types of information. The input part 113 is an input device for inputting various types of information and is, e.g., an input device such as a mouse, a keyboard, or the like. The input part 113 receives an operation input from an operator or the like, and inputs operation information indicating the received operation content to the control part 115.

The storage part 114 is a storage device that stores various types of data. For example, the storage part 114 is a storage device such as a hard disk, a solid state drive (SSD), or an optical disk. Further, the storage part 114 may be a rewritable semiconductor memory such as a random access memory (RAM), a flash memory, or a non-volatile static random access memory (NVSRAM).

The storage part 114 stores an operating system (OS) or various programs executed by the control part 115. For example, the storage part 114 stores a program including instructions (step groups) for executing the operations of film thickness inspection or positioning and the film formation. Further, the storage part 114 stores various data used in the programs executed by the control part 115. For example, the storage part 114 stores processing condition data 120, training data 121, and model data 122. The storage part 114 can store other data in addition to the data exemplified above. Various programs and data stored in a computer-readable computer recording medium (e.g., a hard disk, an optical disk such as a DVD, a flexible disk, a semiconductor memory, or the like) may be used. Various programs and data can be transmitted from other devices at any time and used online.

The control part 115 is a device that controls the control device 100. Specifically, the control part 115 is an electronic circuit such as a central processing unit (CPU) or a micro processing unit (MPU), or an integrated circuit such as an application specific integrated circuit (ASIC) or a field programmable gate array (FPGA). The control part 115 has an internal memory for storing programs and data, reads various programs stored in the storage part 114, and executes processing of the read programs. The control part 115 functions as various processing parts by operating programs. Specifically, the control part 115 has a system control part 130 that controls individual components of the film forming system 10 and controls the film formation, a first measurement control part 131, a second measurement control part 132, a generation part 133, and a determination part 134. In the present embodiment, the case where the control part 115 has the system control part 130 to the determination part 134 has been described as an example, but the functions of the system control part 130 to the determination part 134 may be realized in a distributed manner by multiple control parts.

Here, prior to the description of the configuration of the control device 100 regarding film thickness inspection and positioning, the positioning of the present embodiment will be briefly described. Recently, as the miniaturization of semiconductor devices progresses, in the manufacturing process of very large scale integration (VLSI) semiconductors, for example, the miniaturization has already advanced to the nm (nanometer) scale. Therefore, higher accuracy is required for the positioning of the measurement area R in the inspection area T1. In order to clearly explain the high-precision positioning of the present embodiment, positioning in a comparative embodiment different from the present embodiment will be described first.

The positioning in the comparative embodiment is performed using image processing. Specifically, an inspection apparatus in the comparative embodiment includes an imaging part such as a charge coupled device (CCD) that acquires a surface image of the substrate W, and a signal control part that processes an image signal from the imaging part. The signal processing part is connected to the control device 100, and the control device 100 has an image processing program. As schematically shown in FIG. 3 illustrating the positioning of the measurement area R in the comparative embodiment, in the image processing program, first, a reference point RP is identified from the surface image of the substrate W, and the measurement area R is positioned at the reference point. Then, based on the movement distance L from the preset reference point RP to the inspection area T1, the coaxial probe 13 is moved to appropriately locate the measurement area R within the inspection area T1.

The positioning accuracy in the comparative embodiment depends on the identification accuracy of the reference point RP identified from the surface image. For example, when the reference point RP is set at the intersection point of contour lines F (thick lines in FIG. 3) of scribe lines forming a flat pattern 34, the reference point RP is identified by identifying the contour lines F from the surface image. The contour lines F are identified by acquiring differential signals such as brightness differences between adjacent pixels among multiple pixels constituting the surface image and by defining the boundary of adjacent pixels where the difference is maximum. Therefore, the identification accuracy of the reference point depends on adjacent pixels that are part of the multiple pixels constituting the surface image.

Further, along with the miniaturization of semiconductor devices as described above, further enhancement in the resolution of the surface image is required. Since highly confidential patterns of the substrate W are reflected in the surface image, the handling of the acquired surface image may become an issue. In contrast to the inspection apparatus of the comparative embodiment as described above, the inspection apparatus 1 of the present embodiment performs high-precision positioning without using such image processing. For example, the high-precision positioning is performed using either an absorbance spectrum or a reflectance spectrum obtained by spectroscopic measurement of reflected light over the entire measurement area R. In the present embodiment, in addition to the absorbance spectrum or the reflectance spectrum, an intensity spectrum of reflected light from the measurement area R or an absorption intensity spectrum may also be used. In the present disclosure, a spectrum showing absorption or reflection characteristics with respect to the wavelength of the measurement light irradiated onto the measurement area R is referred to as a “characteristic spectrum.” In the following description, a case where a reflectance spectrum is used will be described.

Next, the characteristics in the reflectance spectrum of the reflected light used for the positioning of the present embodiment will be described. FIGS. 4A to 4C are longitudinal side views of the substrate W, showing the process of moving the measurement area R from the non-inspection area T2 adjacent to the inspection area T1 toward the inspection area T1. The non-inspection area T2 shown in FIGS. 4A to 4C may be, e.g., an area on the flat pattern 34 such as scribe lines. The surface film 33 is formed to have a substantially uniform thickness relative to the surface of the underlying layer 31 of the substrate W. In FIG. 4A, the measurement area R is located at the measurement position I on the non-inspection area T2. In FIG. 4B, the measurement area R is located at the measurement position II, which is the boundary between the inspection area T1 and the non-inspection area T2. In FIG. 4C, the measurement area R is located at a measurement position III on the inspection area T1 (the inspection area where spectroscopic measurement is performed). FIG. 4D shows a case where the surface film 33 formed on the uneven pattern 32 contains voids 35 when the measurement area R is located at the measurement position III. FIG. 5 is a graph illustrating reflectance spectra in the case where the measurement area R is located as shown in FIGS. 4A to 4C.

In the reflectance spectra (characteristic spectra) shown in FIG. 5, there are intersection points where the reflectance (value) is the same at the same wavelength regardless of the arrangement (measurement position) of the measurement area R. Hereinafter, the wavelength at which multiple reflectance spectra obtained by changing the surface pattern of the substrate W (substrate structure) corresponding to the measurement area R intersect as shown in FIGS. 4A to 4C will be referred to as a “singular point.” The reflectance spectra of the inspection area T1, the non-inspection area T2, and the boundary therebetween are generally different from each other except for singular points P1 and P2. Therefore, by measuring the reflectance spectra, it is possible to determine whether the measurement area is located in the inspection area T1, the non-inspection area T2, or the boundary between the inspection area T1 and the non-inspection area T2.

The singular points P1 and P2, including singular points other than intersection points to be described later, appeared at least once in reflectance spectra measured for substrates W in which the shapes of the uneven patterns 32 are different or the film qualities or film thicknesses of the surface films 33 are different. Thus, the inventors speculated as follows and considered using the singular points for the positioning of the measurement area R.

The measurement light includes, e.g., light of multiple wavelengths. When the measurement light is substantially reflected by the patterns 32 and 34 under the surface film 33, the optical characteristics of the reflected light, such as reflectance and the like, change depending on the wavelength. In other words, the reflectance spectrum changes depending on the shapes of the patterns 32 and 34. In the film formation performed by the film forming system 10, the surface films 33 are formed to have substantially the same thickness on upper surfaces 32a and 34a of the patterns 32 and 34 that effectively reflect the measurement light. The reflected light from the reflection of the measurement light is also an interference wave in which reflection and interference occur depending on the wavelength, and the interference wave changes depending on interference factors and absorption factors. Both the interference factors and the absorption factors have, as common factors, the film thickness and the refractive index determined by the composition of the film. Therefore, it can be inferred that, although the waveform varies depending on the shapes of the patterns 32 and 34, if the compositions and the film thicknesses of the surface films 33 are substantially the same, a singular point where the reflectance is the same naturally appears at least at one wavelength in the reflectance spectrum.

Therefore, as shown in FIG. 5, the reflectance spectra in the surface films 33 having substantially the same thickness formed on different pattern shapes exhibit different waveforms in the wavelength ranges before and after the singular points P1 and P2. Hereinafter, the adjacent wavelength ranges before and after the wavelengths of the singular points P1 and P2 may be referred to as an “adjacent wavelength range.”

In the adjacent wavelength ranges, the wavelength ranges outside the singular points that do not include the wavelengths of the singular points as shown in FIG. 5 are defined as Δλ1, Δλ2, and Δλ3. In the wavelength ranges Δλ1 and Δλ3, the reflectances at the measurement positions I to III are different, that is, the waveforms of the reflectance spectra are different. In the wavelength range Δλ2, the reflectances at the measurement positions I and II are substantially the same, that is, the waveforms of the reflectance spectra are substantially the same. Even in the same wavelength range Δλ2, the reflectances at the measurement positions I and II are different from that at the measurement position III, and the waveforms of the reflectance spectra are different. The difference in the waveforms of the reflectance spectra caused by the difference in the shapes of patterns provided in the measurement area R may be clearly recognized from the reflectance at a single wavelength or from the waveform of the reflectance spectrum in the wavelength ranges outside the singular points.

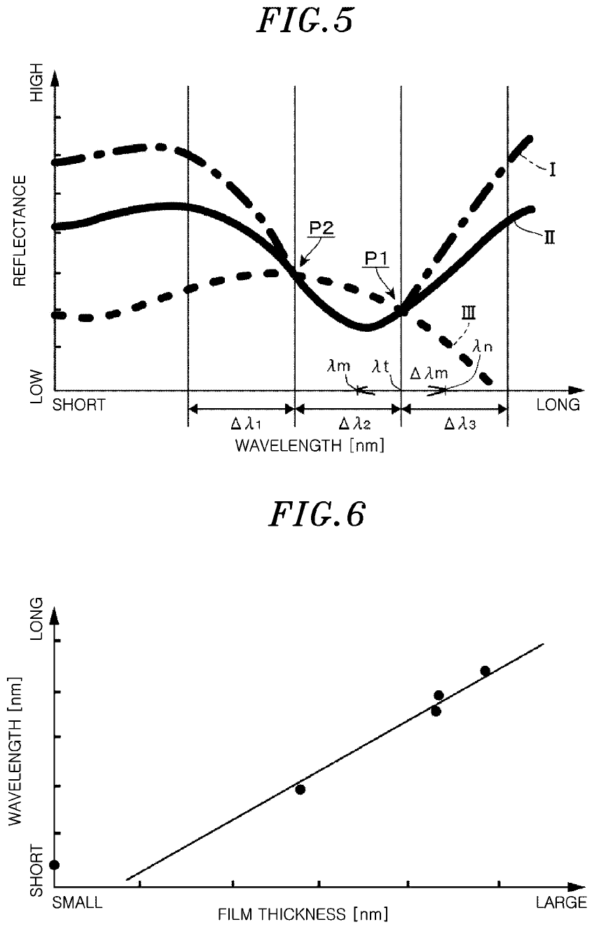

Therefore, in the case of performing spectroscopic measurement in a state where the measurement area R is displaced on the surface films 33 having the same thickness, even if the waveform of the reflectance spectrum changes due to the displacement, a singular point where the reflectance is the same at a predetermined wavelength appears. The wavelength of the singular point changes depending on the film thicknesses of the surface films 33 when the compositions of the surface films 33 are common. For example, FIG. 6 is a graph showing changes in the wavelength of the singular point with respect to a film thickness of a SiN film. As illustrated in FIG. 6, the film thicknesses of the surface films 33 having the same composition and the wavelength of the singular point are proportional to each other, for example. As the film thickness increases, the wavelength of the singular point also increases. In the present embodiment, the measurement area R is positioned using the characteristics of the singular point and the measurement results of the reflectance spectrum in the inspection area T1. Hereinafter, the data showing the correlation between the film thickness and the wavelength of the singular point as shown in FIG. 6 may be referred to as “film thickness-singular point correlation data.”

The positioning of the measurement area R in the present embodiment is performed by a generation operation for generating a prediction model (training model) based on training data of the film thickness and the reflectance spectrum of the inspection area T1, and a determination operation for determining whether or not the measurement area R is located in the inspection area T1 based on the prediction model. If it is determined in the determination operation that the measurement area R is not located in the inspection area T1, the measurement area R is moved and the determination operation is performed again, and those operations are repeated to position the measurement area R. The measurement of the reflectance spectrum for generating the prediction model is performed using a training substrate W1 formed in the same manner as the substrate W to be inspected.

Referring back to the description of the control device 100, the training data 121 in the storage part 114 is training data used for generating the prediction model. The training data 121 is multiple sets of correlation data in which a reflectance spectrum obtained by measuring the inspection area T1 of the training substrate W1 (to be described later) calculated by the second measurement control part 132, singular point information of the reflectance spectrum, and the film thickness of the surface film 33 of the training substrate W1 are correlated. Specifically, the reflectance spectrum is a reflectance spectrum in the adjacent wavelength range as described above. Since the reflectance spectrum exhibits various waveforms, it is difficult to generalize the adjacent wavelength range of the reflectance spectrum used for the training data. However, for example, the wavelength range may be appropriately set to include the wavelengths before (short wavelength) and after (long wavelength) the singular point, or to include the wavelength range before or after the singular point. The width of the adjacent wavelength range may be, e.g., about 50 nm to 200 nm. A smaller width is preferable in order to improve the efficiency of the generation operation and the determination operation. For example, a wavelength at which the reflectance difference between waveforms is large enough to sufficiently identify the waveforms, for example, a wavelength λm at which the reflectance at the measurement positions I and II becomes maximum, is adopted for a lower limit value of an adjacent wavelength range ΔΔm illustrated in FIG. 5. An upper limit value λn of the adjacent wavelength range Δλm is set as λn=λt×2−λm such that the wavelength difference from the wavelength λt at the singular point P1 to the upper limit value λn becomes the same as the wavelength difference from the wavelength λt to the lower limit wavelength λm. When multiple singular points P1 and P2 exist as shown in FIG. 5, the width of the adjacent wavelength range Δλm is set to about 50 nm, for example. In this case, the difference in reflectance spectra becomes clear, thereby allowing effective and efficient generation and determination operations.

Here, the correlation data constituting the training data 121 used for generating the prediction model includes multiple sets of data on different thicknesses of the surface film 33. Further, multiple sets of correlation data on the same film thickness may be obtained in consideration of variation in the reflectance spectrum or the singular point due to film formation. The correlation data is acquired by obtaining the reflectance spectrum measured by the measuring device via the external I/F part 111 and by obtaining the film thickness or the singular point manually input by an operator from the input part 113, and is stored as the training data 121 in the storage part 114.

The generation part 133 performs machine learning on the training data 121, and stores, as the model data 122, the prediction model of the characteristic spectrum correlated with the thickness of the surface film 33 in the storage part 114. For example, the generation part 133 performs machine learning on the training data 121 using a linear regression algorithm, and generates a prediction model that has trained the relationship between multiple sets of correlation data in the training data 121. For example, the generation part 133 generates a prediction model in which the reflectance spectrum in the adjacent wavelength range and the film thickness of each set of correlation data are trained by linear regression. The film thickness included in each set of correlation data of the training data 121 has a one-to-one correspondence relationship with the wavelength of the singular point as shown in FIG. 6, and thus can be replaced with the singular point information. Therefore, the case where the prediction model is generated from at least the singular point information including the wavelength and the reflectance spectrum is also included in the technical scope of the present disclosure. Further, the singular point information in the correlation data may include the reflectance and the wavelength of the singular point, and may include only the wavelength without including the reflectance.

Here, in the present embodiment, the prediction model was generated using a linear regression algorithm as machine learning to prevent overfitting (excessive training) in the training data 121. However, it is also possible to use advanced machine learning algorithms such as neural networks or advanced regression analysis beyond linear regression.

Here, the training model in the present disclosure is not limited to the case where the training model is created based on the result of machine learning of the training data 121. For example, “training” in the present disclosure also includes a case where singular points and reflectance spectra for multiple training substrates W1 are acquired for each film thickness, and a prediction model indicating the correlation between the film thickness and the singular point or the reflectance spectrum (reflectance at each wavelength) is generated by arithmetic averaging.

The second measurement control part 132 controls the spectroscopic measurement of the substrate W and the training substrate W1, and calculates the reflectance spectra of the substrate W and the training substrate W1. Specifically, the second measurement control part 132 controls the irradiator 14 to irradiate measurement light and controls the measuring device 15 to detect reflected light from the measurement area R that is the irradiation area. The measuring device outputs data of the signal intensity of the detected light to the external I/F part 111. The second measurement control part 132 performs spectroscopic analysis such as a Fourier transform on the signal intensity data output by the measuring device 15, and calculates the reflectance spectrum.

In the determination operation for the positioning, the determination part 134 determines whether or not the measurement area R is located in the inspection area T1 from the reflectance spectrum measured for the substrate W to be subjected to film thickness inspection by using the prediction model. Specifically, first, the determination part 134 derives, from the model data 122, the reflectance spectrum of the adjacent wavelength range in the inspection area T1 corresponding to the film thickness using the film thickness as an explanatory variable and the reflectance spectrum of the adjacent wavelength range as an objective variable. In the reflectance spectrum measured for the substrate W to be inspected, the reflectance at the wavelength of the singular point corresponding to the film thickness of the surface film 33 is acquired and set as the singular point information. By determining whether or not the singular point information acquired from the substrate W to be inspected matches the singular point information derived from the reflectance spectrum of the prediction model, it is determined whether the arrangement state of the measurement area R can be determined by the determination operation of the present embodiment.

If it is determined that the information matches, the determination part 134 compares the derived reflectance spectrum with the measured reflectance spectrum to determine whether they match or not, thereby determining the arrangement state of the measurement area R relative to the inspection area T1. Specifically, when it is determined that the derived reflectance spectrum and the measured reflectance spectrum substantially match, it is determined that the measurement area R is located in the inspection area T1, and when it is determined that they do not match, it is determined that the measurement area R is not located in the inspection area T1. The case where the compared reflectance spectra substantially match may be, e.g., the case where the reflectance matches by 80% or more, preferably 90% or more, with respect to the wavelength. In determining whether or not the reflectance spectra match, “the case where the reflectance spectra match” is not limited to the case where the reflectances strictly match at each wavelength. For example, when the reflectance is expressed in percentage, if the measured reflectance spectrum falls within +5% of the reflectance in the derived reflectance spectrum at each wavelength, it may be determined that the reflectance spectra match.

The first measurement control part 131 that performs measurement control for film thickness inspection detects the interference intensity spectrum of light reflected from the upper and bottom surfaces of the surface film 33 using, e.g., the measuring device 15, and calculates the film thickness using parameters related to the substrate W or the refractive index of the surface film 33 stored in the storage part 114 (spectroscopic interference type film thickness measurement). The determination part 134 determines whether or not the calculated film thickness of the surface film 33 is within a preset allowable range for film thickness.

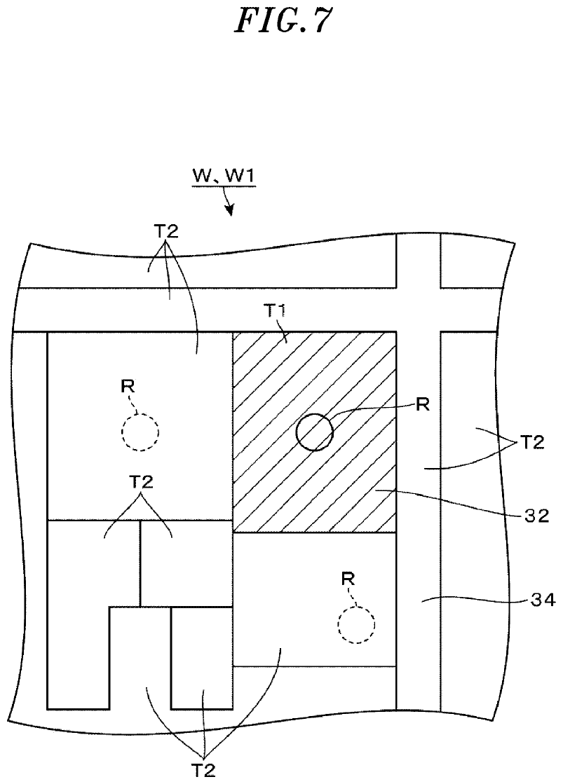

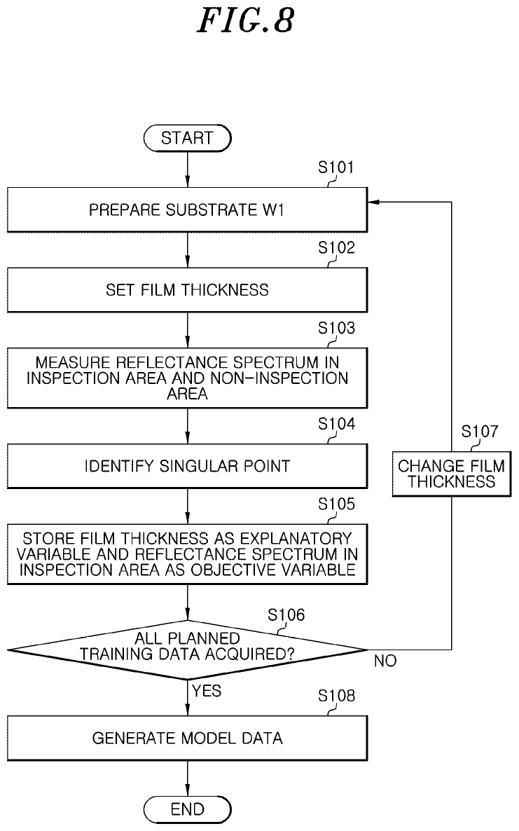

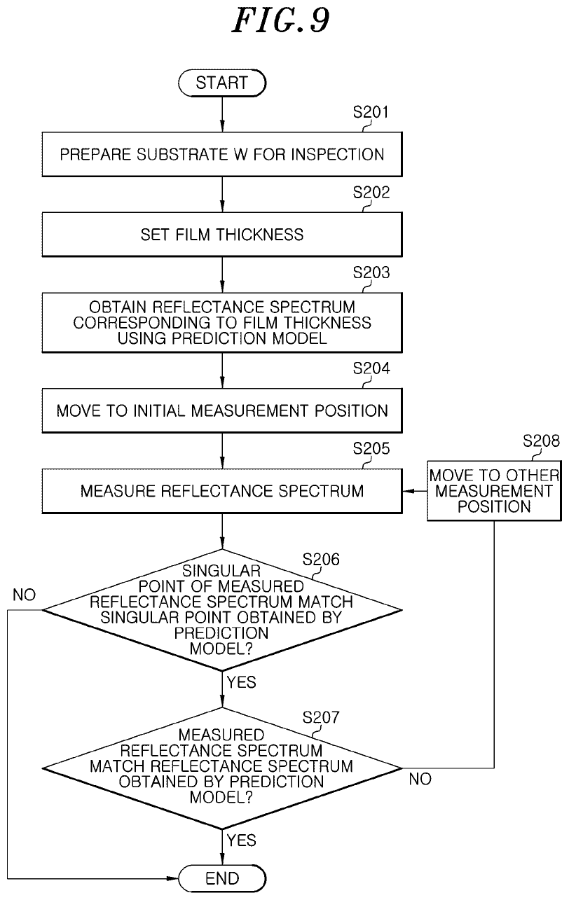

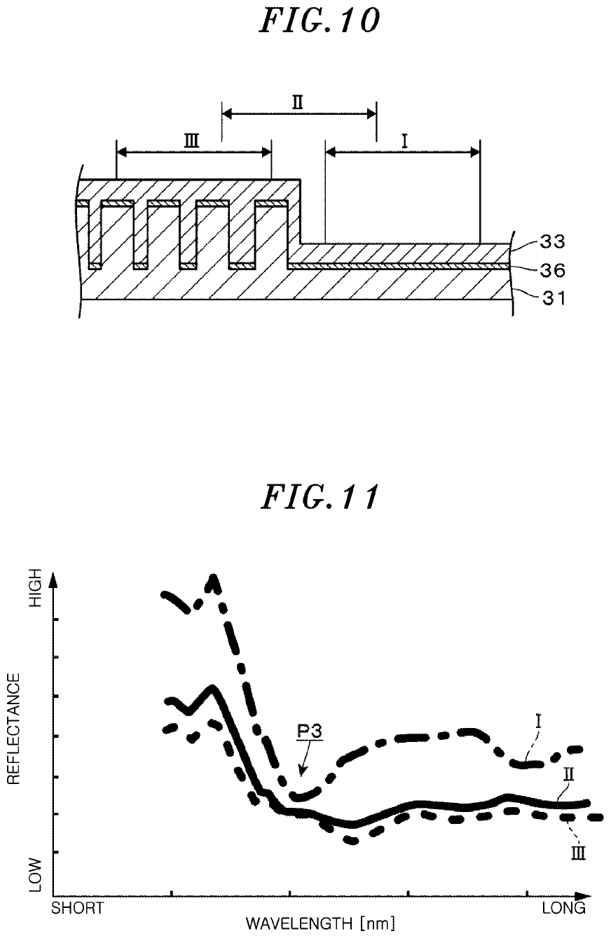

Hereinafter, various operations for positioning in the present embodiment will be described. FIG. 7 is a plan view showing the inspection area T1 and the non-inspection area T2 of the substrate W and the training substrate W1 in the positioning of the measurement area R of the present embodiment. FIG. 8 is a flowchart showing a generation operation, and FIG. 9 is a flowchart showing a determination operation and a movement operation.

In the generation operation, first, the training substrate W1 having the surface film 33 and the same pattern as that of the substrate W to be subjected to film thickness inspection is prepared (step S101). In the training substrate W1, film formation is performed on a substrate having the same pattern as that of the substrate W in the film forming system 10 to be described later, thereby forming the surface film 33. The surface film 33 of the training substrate W1 does not contain voids in the range where the measurement area R is located and is free from film thickness defects, i.e., defects in film formation.

The second measurement control part 132 sets the film thickness of the surface film 33 of the training substrate W1 (step S102). The film thickness is an average film thickness of the surface film 33 on the inspection area T1 of the training substrate W1 and the non-inspection area T2 adjacent thereto, and may be, e.g., an estimated film thickness without being limited to an actual measurement value obtained by film thickness measurement. The estimated film thickness is, e.g., an estimated film thickness determined from film formation conditions of the film formation in the film forming system 10, or a target film thickness set in the film formation, and can be regarded as equivalent to the average film thickness obtained by actual measurement.

Next, the training substrate W1 is placed on the stage 21, and the collimator lens 12 is moved by the moving mechanism to locate the measurement area R in the inspection area T1 (see FIG. 7). In the training stage, the measurement area R may be located in the inspection area T1 using a hyperspectral camera or image processing in a comparative embodiment.

The measurement part 11 and the second measurement control part 132 measure the reflectance spectra of the inspection area T1 and the non-inspection area T2 on the training substrate W1 (step S103). In order to measure the reflectance spectrum of the non-inspection area T2, the collimator lens 12 (the measurement area R) is moved to the non-inspection area T2 after measuring the reflectance spectrum of the inspection area T1, thereby obtaining the reflectance spectrum different from that of the inspection area T1.

Then, the singular point of the reflectance spectrum of the inspection area T1 is identified (step S104). The singular point can be identified from the intersection point between the reflectance spectrum of the inspection area T1 and the reflectance spectrum of the non-inspection area T2, for example. Alternatively, the singular point may be obtained by identifying a wavelength from the film thickness of the training substrate W1 using the film thickness-singular point correlation data described above, and identifying the reflectance from the measured reflectance spectrum of the inspection area T1 based on that wavelength. In this case, the measurement of the reflectance spectrum of the non-inspection area T2 in step S103 may not be performed, and the identification of the singular point (step S104) may not be performed.

The generation part 133 stores the set film thickness of the training substrate W1, the measured reflectance spectrum of the inspection area T1, and the identified singular point information in the training data 121 as data correlated with each other (step S105). Further, the wavelength of the singular point is stored as the singular point information. Next, the training data 121 is stored with the film thickness as an explanatory variable and the reflectance spectrum as an objective variable. Regarding the reflectance spectrum to be stored in the training data 121, the entire measured wavelength range may be stored, or only the adjacent wavelength range may be stored to reduce the amount of data.

Next, the generation part 133 determines whether or not all planned training data have been acquired (step S106). The planned training data refer to multiple sets of correlation data for the substrates W having the surface films 33 with various thicknesses required to generate the model data, and the prediction model. The number of substrates W and the film thicknesses are predetermined according to the number of substrates W and the thickness of the surface film 33 required to generate the prediction model.

When it is determined that all planned training data have not been acquired (No in step S106), the film thickness is changed (step S107) and a substrate W is prepared (step S101). Then, the steps S102 to S106 described above are performed in the same manner. By repeating the above processes until it is determined that all planned training data have been acquired (Yes in step S106), multiple sets of data in which the film thickness, the reflectance spectrum, and the singular point information are correlated for the substrates W having the surface films 33 with different film thicknesses are stored in the training data 121. Thereafter, the generation part 133 performs machine learning on the training data 121 to generate a prediction model (step S108), stores the prediction model as the model data 122 in the storage part 114, and terminates the generation operation.

FIG. 9 is a flowchart showing an example of the determination operation and the movement operation in the method according to the embodiment. In the determination operation, first, a substrate W to be inspected, having the surface film 33 is prepared (step S201), and the substrate W is placed on the stage 21 by a transfer mechanism such as a transfer arm. The second measurement control part 132 sets the film thickness of the surface film 33 of the substrate W (step S202). The film thickness is set in the same manner as the film thickness of the training substrate W1 in the generation operation.

The determination part 134 derives the reflectance spectrum corresponding to the set film thickness using the prediction model stored as the model data 122 (step S203). Specifically, the determination part 134 acquires the reflectance spectrum of the adjacent wavelength range from the prediction model using the acquired film thickness as an explanatory variable and the reflectance spectrum of the adjacent wavelength range as an objective variable. Further, the determination part 134 reads out the singular point information (the wavelength of the singular point) stored as the training data 121 in association with the film thickness, and derives the reflectance (model reflectance) at the singular point using the reflectance spectrum acquired from the prediction model.

Next, the moving mechanism of the inspection apparatus 1 moves the collimator lens 12 and the coaxial probe 13 to locate the measurement area R at an initial measurement position (step S204). The initial measurement position is an arbitrary position in the inspection area T1 or the non-inspection area T2. The positioning of the measurement area R at the initial measurement position is performed with the inspection area T1 as a target based on the previously obtained pattern arrangement information of the substrate W, for example, by visual measurement using a magnifying glass or an enlarged image captured by a camera to such an extent that the pattern arrangement cannot be recognized. Alternatively, the positioning of the measurement area R at the initial measurement position may be performed by presetting an approximate relative movement amount from a reference position, such as an alignment mark on the substrate W, to the inspection area T1, and moving the measurement area R with the inspection area T1 as a target from the reference position based on the relative movement amount. The positioning of the measurement area R does not require high precision compared to the positioning performed by the determination and movement operations of the present disclosure. The measurement area R positioned as described above is located in an area including the inspection area T1 or the non-inspection area T2, or in an area other than these areas.

The measurement part 11 and the second measurement control part 132 measure the reflectance spectrum by spectroscopic measurement at the initial measurement position (step S205, a step of measuring a characteristic spectrum). The determination part 134 identifies the singular point of the measured reflectance spectrum. In order to identify the singular point, the wavelength of the derived singular point information and the reflectance at that wavelength are identified from the reflectance spectrum (measured reflectance), for example. Then, the determination part 134 determines whether or not the model reflectance and the measured reflectance at the wavelength serving as the singular point match (step S206).

When the determination part 134 determines that the difference between the model reflectance and the measured reflectance is greater than or equal to a preset tolerance and that the singular points do not match (No in step S206), the determination operation is terminated. When they do not match, the determination operation is terminated because it is considered that there are external factors such as film thickness defects of the surface film 33 at the initial position, errors in setting the measurement area R at the initial position, or errors in the inspection apparatus 1 itself and that it is difficult to appropriately perform the determination operation subsequent thereto. When the determination part 134 determines that the identified model reflectance and the measured reflectance match (the singular points match) (Yes in step S206), the above-described external factors are not considered and the determination operation can be performed appropriately, so that the determination operation is continued.

Next, the determination part 134 compares the measured reflectance spectrum (inspection target spectrum) in the adjacent wavelength range with the derived reflectance spectrum (reference spectrum) of the adjacent wavelength range in the inspection area T1 to determine whether or not they match (step S207). In this step, the arrangement state of the substrate W to be inspected relative to the measurement area R is determined (step of determining the arrangement state). The comparison may be performed by comparing the waveforms of the reflectance spectra in the adjacent wavelength range, or by comparing the reflectance or the amount of change in reflectance at the wavelength other than the wavelength of the singular point in the adjacent wavelength range. By comparing the reflectance spectra of the adjacent wavelength range, the reflectance spectra can be clearly compared, and the data processing load of the determination part 134 can be reduced to accelerate the determination process.

When it is determined that the reflectance spectra in the adjacent wavelength range match (Yes in step S207), it can be determined that the measurement area R is located in the inspection area T1. Since the positioning of the measurement area R has been completed, the determination operation is terminated. When it is determined that the reflectance spectra in the adjacent wavelength range do not match (No in step S207), it can be determined that the measurement area R is not located in the inspection area T1, and it is assumed that the measurement area R is located in the non-inspection area T2 or at the boundary between the inspection area T1 and the non-inspection area T2. In this case, since the positioning of the measurement area R has not been completed, the movement operation is performed. In the movement operation, the moving mechanism of the inspection apparatus 1 moves the collimator lens 12 and the coaxial probe 13 to move the measurement area R again, for example (step S208, a step of moving the measurement area). The movement of the measurement area R is performed in the same manner as the positioning of the measurement area R at the initial measurement position (step S204).

Then, the steps S205 to S207 of the determination operation are performed. The determination operation and the movement operation are repeatedly performed until it is determined that the reflectance spectra in the adjacent wavelength range match (Yes in step S207) and that the measurement area R is located in the inspection area T1. As a result, the measurement area R can be located in the inspection area T1. According to the positioning method of the present embodiment, whether or not the measurement area R is positioned in the inspection area T1 can be determined based on the reflectance spectrum of the reflected light from the entire measurement area R. Thus, in the determination method of the present embodiment, an optical method in which measurement errors are unlikely to occur is used, and since the reflectance spectrum of the reflected light from the entire measurement area R is used, it is possible to determine the position of the measurement area R with higher precision compared to the image processing in the comparative embodiment.

When the positioning of the measurement area R in the inspection area T1 is completed, the inspection apparatus 1 performs film thickness inspection. In the film thickness inspection, the first measurement control part 131 calculates the film thickness using the reflectance spectrum measured in the positioned measurement area R and the parameters related to the substrate W or the refractive index of the surface film 33 stored in the storage part 114. The determination part 134 determines whether or not the calculated film thickness of the surface film 33 is within a preset allowable range for film thickness, and inspects whether or not the surface film 33 has been appropriately formed.

Further, the film thickness inspection may be repeated at multiple locations in the inspection area T1. In this case, the film thickness inspection is repeatedly performed by moving the measurement area R by a preset displacement amount. The preset displacement amount is, e.g., a length greater than or equal to the diameter of the measurement area R in one direction. Whenever the measurement area R moves, the steps S205 to S207 of the determination operation described above are performed, and the film thickness inspection is performed after it is confirmed that the measurement area R is located in the inspection area T1. As a result, the inspection can be performed within the inspection area T1 without extending beyond the inspection area T1.

### (Examples of Other Reflectance Spectra)

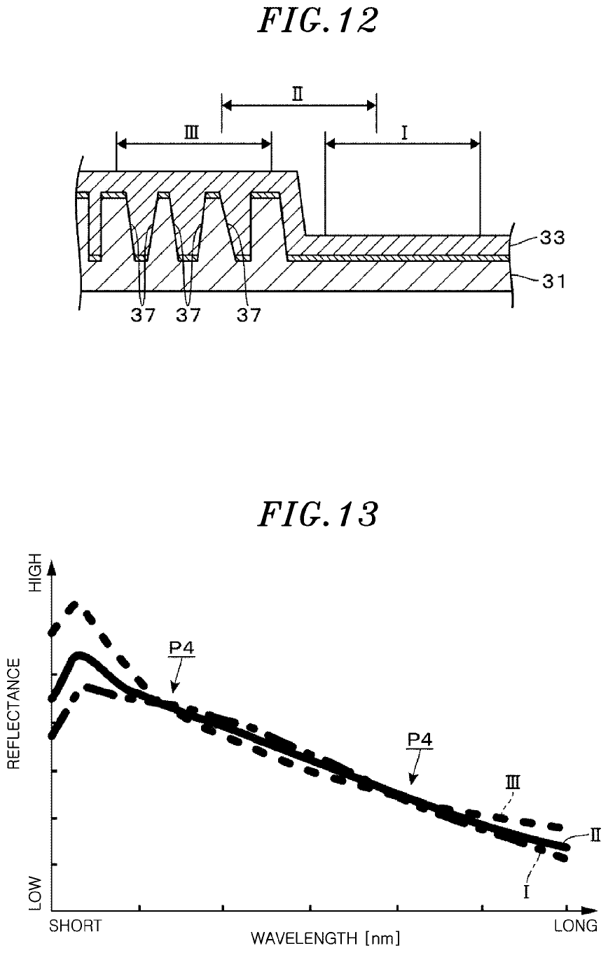

Examples of reflectance spectra different from the example illustrated in FIG. 5 will be described. FIG. 10 is a longitudinal side view illustrating a substrate W in which a film 36 that easily reflects light is formed in the base portion of the surface film 33. FIG. 11 is a graph showing reflectance spectra at the measurement positions I to III shown in FIG. 10. FIG. 12 is a longitudinal side view illustrating a substrate W in which the uneven pattern 32 has tapered portions. FIG. 13 is a graph showing reflectance spectra at the measurement positions I to III shown in FIG. 12.

In the substrate W shown in FIG. 10, the film 36 that easily reflects light may be formed between the underlying layer 31 and the surface film 33 in the non-inspection area T2, for example. In this case, as shown in FIG. 11, the reflectance of the spectroscopic measurement at the measurement position I increases overall, so that the waveform of the reflectance spectrum at the measurement position I is shifted upward relative to the waveforms of the reflectance spectra at the measurement positions II and III.

Therefore, unlike the example shown in FIG. 5, in the example shown in FIG. 11, the reflectance spectra of the measurement positions I to III do not intersect, and there is no intersection point. In this case, a singular point P3 is set at a position where the difference in reflectance values of the reflectance spectra becomes minimum. The reflectance of the singular point P3 in this case is defined as the reflectance of the reflectance spectrum at each of the measurement positions I to III at the wavelength of the singular point P3. In other words, the singular point P3 in this case has the same wavelength, but the reflectance is set for the reflectance spectrum of each of the measurement position I to III. In this case, for example, the reflectance is not included in the above-described singular point information in the present embodiment, and the step S206 of comparing singular points is not performed.

When there is no intersection point in the reflectance spectra as described above, the wavelength range extending before and after the wavelength of the singular point P3 is set as the adjacent wavelength range, for example, and the width of the adjacent wavelength range is set to about 50 nm to 200 nm.

The uneven pattern 32 of the substrate W shown in FIG. 12 has convex portions that become wider toward the bottom side, and the side surfaces of the uneven pattern 32 have inclined side surfaces 37. In this case, the measurement light tends to be diffusely reflected by the inclined side surfaces 37, and the reflected light tends to be incident from outside the range of the measurement positions I to III. Thus, as shown in FIG. 13, the reflectance spectra at the measurement positions I to III are similar to each other. However, in this case as well, two singular points P4 that are the intersection points of the reflectance spectra appear.

The wavelength of the singular point P3 described with reference to FIG. 11 substantially matches the wavelength of the singular point determined from the film thickness of the surface film 33 by the correlation data shown in FIG. 6. Further, regarding the two singular points P4 described with reference to FIG. 13, the wavelength of one of the two singular points P4, e.g., the longer wavelength, substantially matches the wavelength of the correlation data shown in FIG. 6. From the appearance examples of the singular points P3 and P4 as described above, it is confirmed that even if another film such as the film 36 or a pattern with a special shape exists at the measurement positions I to III, singular points corresponding to the film quality or film thickness of the surface film 33 appear, and the generation operation and the determination operation of the present embodiment can be performed efficiently using the singular points.

### Effects

According to the inspection apparatus 1 of the present embodiment, the arrangement state of the substrate W to be inspected relative to the measurement area R can be determined by the reflectance spectrum (characteristic spectrum) obtained by irradiating the substrate W with measurement light.

### Modification

In the embodiment described above, in the step S206 of FIG. 9, the reflectances at the singular points are compared to determine whether or not to continue the determination operation. Here, an example in which the reflectance at the singular point of the reflectance spectrum derived from the prediction model (model reflectance) is compared with the reflectance at the singular point of the measured reflectance spectrum (measured reflectance) has been described. The method for identifying the model reflectance is not limited to this example. For example, in the step S105 of FIG. 8, the machine learning may be performed to create a prediction model using the film thickness as an explanatory variable and the singular point information (the wavelength of the singular point and the reflectance at that wavelength) as an objective variable. In this case, in the step S206 of FIG. 9, the reflectances may be compared using the singular point information (reflectance at the singular point) obtained based on the result of inputting the film thickness into the prediction model as the model reflectance.

Further, it is preferable that the density of the uneven pattern 32 is substantially uniform throughout the entire inspection area T1. Accordingly, regardless of the position where the measurement area R is located in the inspection area T1, the density of the uneven pattern 32 becomes the same, and substantially the same reflectance spectrum can be obtained regardless of the measurement position in the inspection area T1. By comparing the reflectance spectrum of the prediction model with the measured reflectance spectrum, whether or not the measurement area R is located in the inspection area T1 can be determined with high accuracy. Further, in the present embodiment, the measurement part 11 can also be used for spectroscopic measurement for positioning, so that the film thickness inspection is performed by spectroscopic interference-based film thickness measurement. However, the present disclosure is not limited thereto, and the film thickness inspection can be performed by, e.g., reflectance spectroscopy or spectroscopic ellipsometry. The positioning in the present disclosure is not necessarily performed by the inspection apparatus for film thickness inspection, and may be performed by another inspection apparatus for performing in-line inspection on the substrate W.

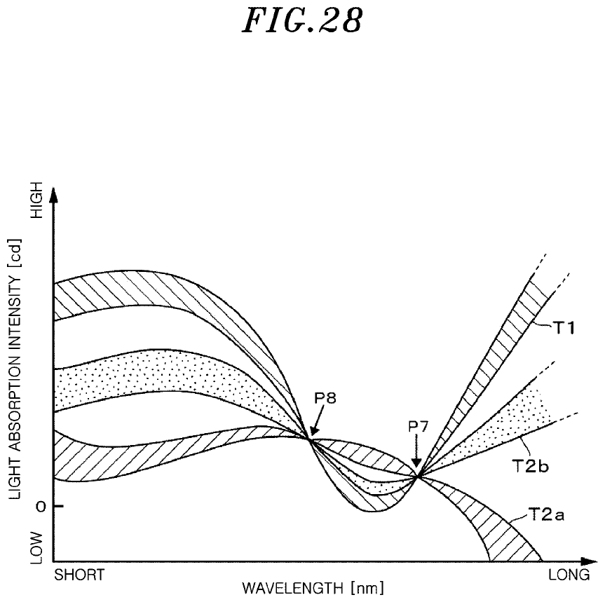

The inspection apparatus 1 of the present embodiment performs positioning using either the absorbance spectrum or the reflectance spectrum as the characteristic spectrum. However, the characteristic spectrum that can be used for positioning is not limited thereto. For example, even when using an intensity spectrum of reflected light or an absorption intensity spectrum (see FIG. 28) that is the difference between the intensity spectrum of irradiation light and the intensity spectrum of reflected light, singular points appear in a similar manner and, thus, they can be handled in the same manner as the reflectance spectrum.

### Modification of First Embodiment

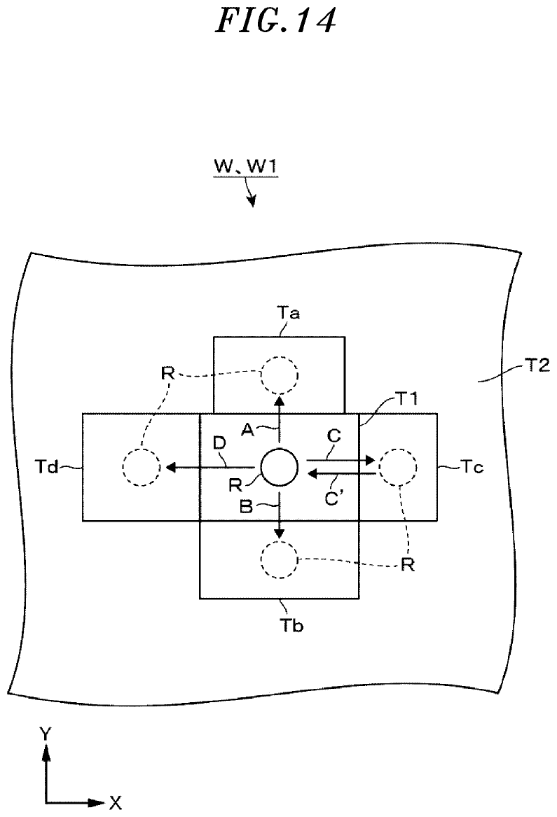

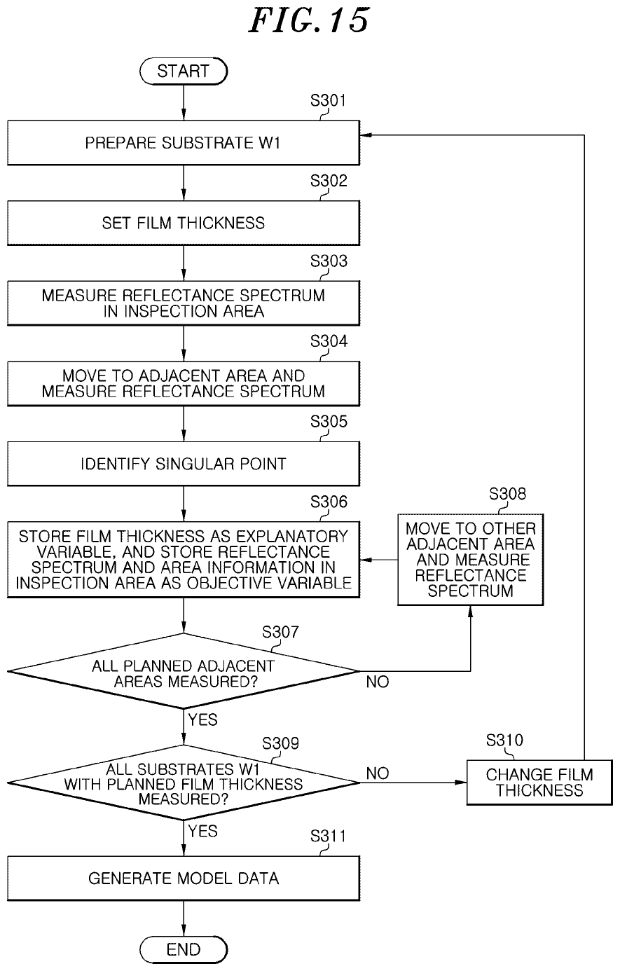

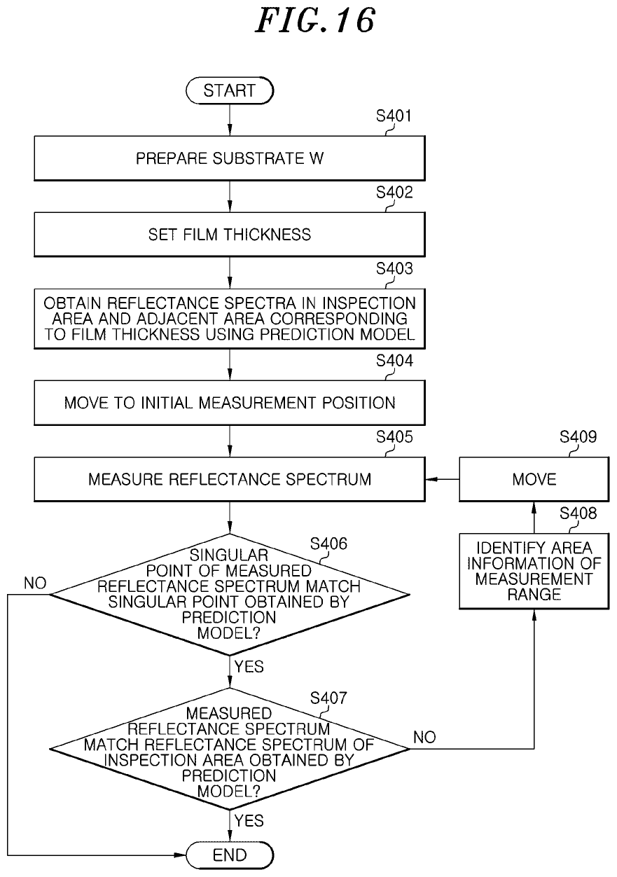

Positioning in the modification will be described with reference to FIGS. 14 to 16. In describing the modification, the differences from the first embodiment will be mainly described, and the description of the same configurations as those of the first embodiment will be omitted. FIG. 14 is a plan view showing the inspection area T1 and the non-inspection area T2 of the substrate W and the training substrate W1 in the positioning of the measurement area R in the modification. FIG. 15 is a flowchart showing a generation operation of the modification. FIG. 16 is a flowchart showing a determination operation and a movement operation of the modification.

As shown in FIG. 14, in the positioning of the measurement area R in the modification, there are adjacent areas Ta, Tb, Tc, and Td in the non-inspection area T2, each including different patterns formed on the underlying layer 31. Different reflectance spectra of the adjacent areas Ta to Td are measured, and data in which the reflectance spectra and the area information indicating the adjacent areas Ta to Td are correlated are stored in the training data 121 to generate the model data 122. In the determination operation, it is possible to determine the location of the measurement area R among the areas T1 and Ta to Td using the model data 122 generated as described above, and the measurement area R is rapidly positioned toward the inspection area T1 based on the relative positional relationship of the adjacent areas Ta to Td with respect to the inspection area T1.

The generation operation of the prediction model in the modification will be described with reference to FIGS. 14 and 15. In the non-inspection area T2 of the substrate W and the training substrate W1, various uneven patterns or flat patterns different from the uneven pattern 32 of the inspection area T1 are formed around the inspection area T1. Since the adjacent patterns include different patterns, the reflectance spectra with different waveforms are measured by the irradiation of the measurement light from the measurement part 11. The areas where the adjacent patterns are provided are respectively set as the adjacent areas Ta to Td. The ranges of the inspection area T1 and the adjacent areas Ta to Td, and the relative positions of the adjacent areas Ta to Td may be predetermined from the design information of the substrate W, or may be obtained in the generation operation to be described later.

Similarly to the first embodiment, first, preparation of the first training substrate W1 (step S301), setting of the film thickness of the surface film 33 for the training substrate W1 (step S302), and measurement of the reflectance spectrum in the inspection area T1 (step S303) are performed. Next, the measurement area R is moved toward the adjacent area Ta, for example, and the reflectance spectrum of the adjacent area Ta is measured (step S304). When the relative position of the adjacent area Ta is not known from design information or the like, the measurement area R is moved from the inspection area T1 in the positive direction of the Y-axis shown in FIG. 14 while measuring the reflectance spectrum, for example. When the reflectance spectrum clearly changes from the reflectance spectrum of the inspection area T1, the area where the measurement area R is located is set as the adjacent area Ta, and the movement to the adjacent area Ta is completed. In this case, a movement amount vector A of the measurement area R may be identified, and the movement amount vector A may be set as the relative position of the adjacent area Ta.

Next, a singular point is identified from the reflectance spectrum of the inspection area T1 and the reflectance spectrum of the adjacent area Ta (step S305). Next, the data (hereinafter, also referred to as “relative data”) in which the singular point information, the measured reflectance spectrum, the film thickness, and the area information are correlated is stored in the training data 121 (step S306). Specifically, the data in which the area information indicating the inspection area T1, the reflectance spectrum of the inspection area T1, the singular point information, and the film thickness are correlated, and the data in which the area information indicating the adjacent area Ta, the reflectance spectrum of the adjacent area Ta, the singular point information, and film thickness are correlated are stored in the training data 121. The film thicknesses and the singular point information substantially match, but the reflectance of the singular point information may differ as described above.

Hereinafter, the above operation will be described in detail. The training is performed with the film thickness as an explanatory variable and the reflectance spectrum and area information as an objective variable, and the results are stored in the training data 121. The relative position may be stored in the storage part 114 or may be stored as data corresponding to the area information in the training data 121 together with or instead of the area information.

Next, the generation part 133 determines whether or not all adjacent areas Ta to Td have been measured (step S307). When the relative positions of the adjacent areas Ta to Td are not known from design information or the like, the determination is made by determining whether or not the relative data for each adjacent area has been acquired to an extent required for positioning based on the accumulated content of the relative data in the training data 121, for example. When it is determined that all planned training data have not been acquired (No in step S307), the measurement area R is moved to another adjacent area, e.g., the adjacent area Tb, and the reflectance spectrum of the adjacent area Tb is measured (step S308). The movement of the measurement area R to the adjacent area Tb is performed in the same manner as the movement from the inspection area T1 to the adjacent area Ta in step S304 described above, and the relative position of the adjacent area Tb can also be determined by a movement amount vector B.

As described for the adjacent area Ta in step S306, the data in which the measured reflectance spectrum, the area information, and the film thickness measured for the adjacent area Tb are correlated are stored in the training data 121 (step S306). The above steps S308, S306, and S307 are also performed for the other adjacent areas Tc and Td. When it is determined that all adjacent areas Ta to Td have been measured (step S307), multiple sets of data regarding the inspection area T1 and the adjacent areas Ta to Td for the first training substrate W1 are stored in the training data 121.

Next, the generation part 133 determines whether or not the training substrates W1 of all planned film thicknesses have been measured (step S309). When it is determined that the training substrates W1 of all planned film thicknesses have not been measured (No in step S309), a second substrate W with a different film thickness is prepared (steps S310 and S301). Then, similarly to the case of the first training substrate W1, the reflectance spectra are measured for the areas T1 and Ta to Td, and the correlated data of the areas T1 and Ta to Td is stored in the training data 121 (steps S302 to S308). By repeating the above processes until it is determined that the training substrates W1 of all film thicknesses have been measured (Yes in step S309), multiple sets of correlated data of the areas T1 and Ta to Td for multiple training substrates W1 with different film thicknesses are stored in the training data 121. The generation part 133 performs machine learning on the training data 121 to generate a prediction model (step S311), stores the prediction model as the model data 122 in the storage part 114, and terminates the generation operation.

The determination operation and the movement operation in the modification will be described with reference to FIG. 16 that is the flowchart showing an example of the determination operation and the movement operation in the method according to the present embodiment. First, a substrate W to be inspected, having the surface film 33, is prepared on the stage 21 (step S401), and film thickness setting for the surface film 33 is performed (step S402). Next, the reflectance spectra of the areas T1 and Ta to Td corresponding to the set film thicknesses are derived using the prediction model stored as the model data 122 (step S403). Specifically, the determination part 134 acquires the reflectance spectra of the areas T1 and Ta to Td from the prediction model using the set film thickness as an explanatory variable and the area information and the reflectance spectra that are correlated as an objective variable. Further, the determination part 134 reads out the singular point information (wavelength of the singular point) stored as the training data 121 in association with the film thickness, and derives the reflectance at the singular point (model reflectance) using the reflectance spectra acquired from the prediction model.

Next, the measurement area R is located at an initial measurement position on the substrate W (step S404), and the reflectance spectrum is measured at the initial measurement position (step S405, a step of measuring a characteristic spectrum). Then, it is determined whether or not the reflectance (measured reflectance) at the singular point identified from the measured reflectance spectrum matches the reflectance (model reflectance) at the singular point of the reflectance spectrum derived from the prediction model (step S406). When it is determined that the reflectances match (Yes in step S406), whether or not the derived reflectance spectrum of the inspection area T1 matches the measured reflectance spectrum is determined (step S407).

When it is determined that the reflectance spectra do not match (No in step S407), the movement operation is performed. First, the determination part 134 identifies the area information and the relative position of the measurement area R (step S408). The identification of the area information and the relative position is performed, e.g., by identifying a reflectance spectrum that matches or most closely approximates the measured reflectance spectrum among the derived reflectance spectra of the adjacent areas Ta to Td, and using the area information and the relative position associated with the identified reflectance spectrum. Regarding the identification of the area information and the relative position, only the relative position may be identified without identifying the area information.

Based on the identified relative position, the moving mechanism of the measurement part 11 moves the measurement area R toward the inspection area T1 (step S409). A specific example will be described with reference to FIG. 14. For example, when the measured reflectance spectrum matches the reflectance spectrum associated with the area information and the relative position (movement amount vector C) indicating the adjacent area Tc, the measurement area R is moved by a vector C′ that is the inverse of the movement amount vector C indicating the relative position. According to the method of the modification in which the movement operation and the determination operation of the steps S405 to S407 are repeatedly performed, the measurement area R can be located in the inspection area T1 efficiently and with high accuracy.

### (Film Forming System 10)

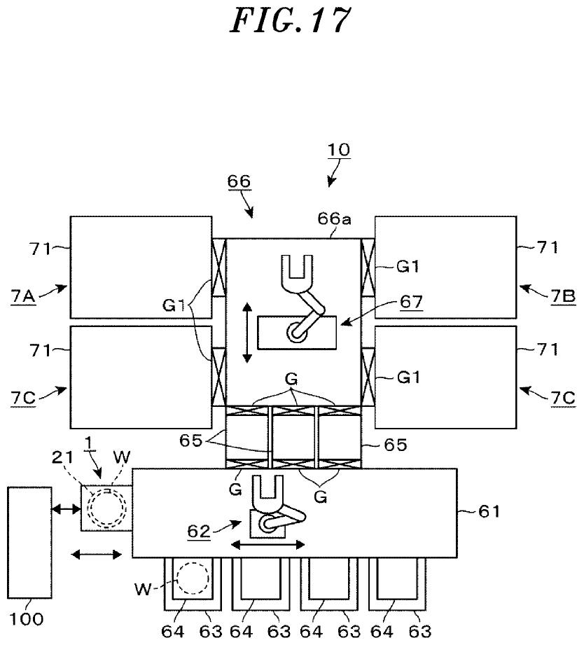

Hereinafter, the film forming system 10 in which the inspection apparatus 1 of the present embodiment and the modification thereof is installed will be described briefly. FIG. 17 is a plan view showing a film forming system 10. The film forming system 10 includes a loader module 61, load-lock modules 65, a vacuum transfer module 66, and first to third processing modules 7A to 7C.

The loader module 61, the load-lock module 65, and the vacuum transfer module 66 are arranged side by side in the front-rear direction in that order.

The loader module 61 includes a housing maintained at an atmospheric pressure, a transfer mechanism 62 for a substrate W provided in the housing, and four load ports 63. The inspection apparatus 1 according to the present embodiment is located in the housing. In each load port 63, a transfer chamber 64 referred to as a front opening unified pod (FOUP) for storing substrates W is placed. The transfer mechanism 62 includes, e.g., an articulated arm capable of moving to the left and right sides, and can transfer a substrate W between the transfer chamber 64 on each load port 63, each load-lock module 65, and the inspection apparatus 1.

In this example, three load-lock modules 65 are provided. Each load-lock module 65 includes a housing, and the housing is connected to the loader module 61 and the vacuum transfer module 66 via gate valves G provided at the front and rear sides thereof.

Each load-lock module 65 is configured such that the pressure in the housing can be changed between an atmospheric pressure and a vacuum pressure in a state where the gate valves G at the front and rear sides of the housing are closed. In addition, a stage (not shown) is provided in the housing. A substrate W may be placed on the stage and transferred to the transfer mechanism 62 and a vacuum transfer mechanism 67 to be described later, each of which accesses the load-lock module 65.

The vacuum transfer module 66 includes a housing 66a and a vacuum transfer mechanism 67 provided in the housing 66a. An exhaust mechanism (not shown) such as a turbo molecular pump is connected to the housing 66a via an exhaust line, and the inside of the housing 66a is maintained in a vacuum atmosphere by an exhaust operation using the exhaust mechanism.

The first to third processing modules 7A to 7C are arranged side by side on left and right side surfaces of the housing 66a of the vacuum transfer module 66 when viewed from the front side. The transfer of the substrate W between the first to third processing modules 7A to 7C and the load-lock modules 65 is performed by the vacuum transfer mechanism 67 including an articulated arm, for example.

The correlation between the processing performed in each of the first to third processing modules 7A to 7C and the series of processes described above will be described. In the first processing module 7A, a COR process for generating reaction products by modifying an oxide film formed on the surface of the underlying layer 31 of the substrate W is performed. In the second processing module 7B, a PHT process for sublimating and removing the reaction products is performed. In the third processing module 7C, film formation for forming the surface film 33 is performed. Each of the processing modules 7A to 7C includes a processing chamber 71 that is evacuated to a vacuum atmosphere, and a placing table 72 provided in the processing chamber 71 to placing the substrate W thereon. Each processing step is performed in the processing chamber 71.

The system control part 130 of the control device 100 outputs control signals to individual components of the film forming system 10 according to each program stored in the storage part 114 to control the operations of the individual components. Specifically, the operation of the first to third processing modules 7A to 7C, the opening and closing of the gate valves G and G1, and the operation of the transfer mechanism 62, the operation of the vacuum transfer mechanism 67, and the like are controlled.

The substrate W in the film forming system 10 is transferred in the following order: the transfer chamber 64→the loader module 61→the load-lock module 65→the vacuum transfer module 66→the first processing module 7A→the second processing module 7B→the third processing module 7C. In this transfer process, the oxide film on the surface of the underlying layer 31 is removed and then, the surface film 33 is formed on the substrate W. Next, the substrate W is transferred in the following order: the third processing module 7C→the vacuum transfer module 66→the load-lock module 65→the loader module 61→the inspection apparatus 1. In this transfer process, the substrate W having the surface film 33 is subjected to film thickness inspection in the inspection apparatus 1. The substrate W that has passed the film thickness inspection is transferred to the transfer chamber 64 and then transferred while being stored in the transfer chamber 64 to a next processing apparatus by a transfer device (not shown). The substrates W that has failed the film thickness inspection is stored in a storage area for failed substrates W (not shown) provided in the loader module 61.

### (Film Forming Module)

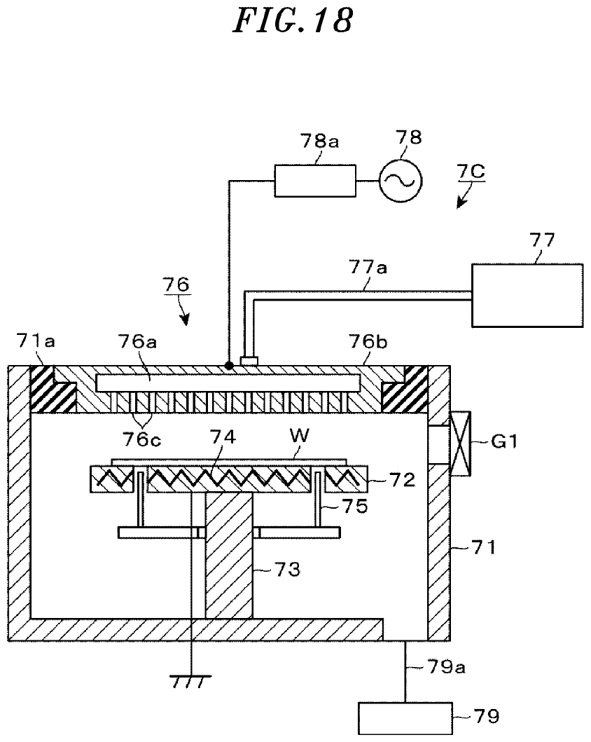

Next, as a representative example of the processing modules 7A to 7C, the third processing module 7C, which is a film forming module, will be described with reference to the longitudinal side view of FIG. 18. A case where film formation is performed as substrate processing will be described as a main example. The third processing module 7C is configured to be airtight, and the processing chamber 71 has a cylindrical shape. The placing table 72 is provided in the processing chamber 71.

The placing table 72 is electrically grounded, and is made of a metal such as nickel. A substrate W is placed on the upper surface of the placing table 72, and the placed substrate W is supported horizontally. The bottom surface of the placing table 72 is electrically connected to a support member 73 made of a conductive material. The placing table 72 is supported by the support member 73. The support member 73 is supported by the bottom surface of the processing chamber 71, and has the lower end electrically connected to the bottom surface of the processing chamber 71. Therefore, the processing chamber 71 is also grounded.

A heater 74 is built into the placing table 72, and the substrate W placed on the placing table 72 can be heated to a predetermined temperature. The placing table 72 is provided with lifter pins 75 for raising and lowering the substrate W. In the case of loading a substrate W, in the third processing module 7C, the lifter pins 75 are raised by a lifting mechanism (not shown) to receive the substrate W from the vacuum transfer mechanism 67 (see FIG. 17). Then, the vacuum transfer mechanism 67 retracts, and the lifter pins 75 are lowered to place the substrate W on the placing table 72.

A shower head 76 formed in a substantially disk shape is provided above the placing table 72 and on the inner side surface of the processing chamber 71. The shower head 76 is supported above the placing table 72 via an insulating member 71a made of ceramic or the like. Accordingly, the processing chamber 71 and the shower head 76 are electrically insulated from each other. The shower head 76 is made of a conductive metal such as nickel or the like.

The shower head 76 has therein a gas diffusion space 76a, includes a shower plate 76b provided to downwardly face the placing table 72, and closes the interior of the processing chamber 71 from the top. Multiple gas injection holes 76c opening toward the gas diffusion space 76a and the placing table 72 are formed in a distributed manner in the shower plate 76b. A gas supply line 77a is connected to the upper part of the shower head 76 to introduce various gases into the gas diffusion space 76a. A gas supply part 77 is connected to the gas supply line 77a.

The gas supply part 77 has gas supply lines respectively connected to gas supply sources of various gases used for forming the surface film 33, which is a SiN film. Each gas supply line appropriately branches to correspond to the film formation process, and is provided with control devices for controlling a gas flow rate, such as valves, e.g., on-off valves, and flow rate controllers, e.g., mass flow controllers. The gas supply part 77 supplies a purge gas, a raw material gas, and a reaction gas to the gas supply line 77a. For example, the purge gas is an inert gas, the raw material gas is SiH₄ (silane) gas, and the reaction gas is NH₃ (ammonia) gas. These gases are diffused in the gas diffusion space 76a and injected from the gas injection holes 76c.

The space surrounded by the bottom surface of the shower head 76 and the upper surface of the placing table 72 forms a processing space where the film formation is performed. The shower head 76 and the placing table 72 function as electrode plates for forming, e.g., capacitively coupled plasma (CCP) in the processing space. A radio frequency (RF) power supply 78 is connected to the shower head 76 via a matching device 78a. In the case of generating plasma in the processing space, the RF power supply 78 supplies a high-frequency power (RF power) in response to the gas supply from the gas supply part 77. As a result, the RF power is applied to the gas supplied from the shower head 76 to the processing space, thereby generating plasma in the processing space.

An exhaust port connected to an exhaust line 79a is formed at the bottom portion of the processing chamber 71, and an exhaust device 79 having a vacuum pump or a pressure control valve is connected to the exhaust line 79a. By the operation of the exhaust device 79, the pressure in the processing chamber 71 is reduced to a predetermined vacuum level.

Next, the sequence of film formation performed on the substrate W in the third processing module 7C under the control of the system control part 130 of the control device 100, which controls film formation, will be briefly described. First, the substrate W is placed on the placing table 72 by the vacuum transfer mechanism 67 of the film forming system 10. In the loaded substrate W, the uneven pattern 32 is exposed on the surface, and the surface film 33 is not formed. In the case of performing film formation on the substrate W, the system control part 130 controls the exhaust device 79 to reduce the pressure in the processing chamber 71 using the exhaust device 79. The system control part 130 controls the gas supply part 77 to supply various gases used for film formation, thereby introducing a processing gas into the processing chamber 71 through the shower head 76. The system control part 130 controls the RF power supply 78 to supply an RF power and generate plasma in the processing space, thereby performing film formation on the substrate W. As described above, the surface film 33 is formed on the substrate W by the third processing module 7C. Then, the lifter pins 75 protrude from the placing table 72 to support the back surface of the substrate W. Accordingly, the substrate W is lifted from the placing table 72 and unloaded by the vacuum transfer mechanism 67.

### Second Embodiment

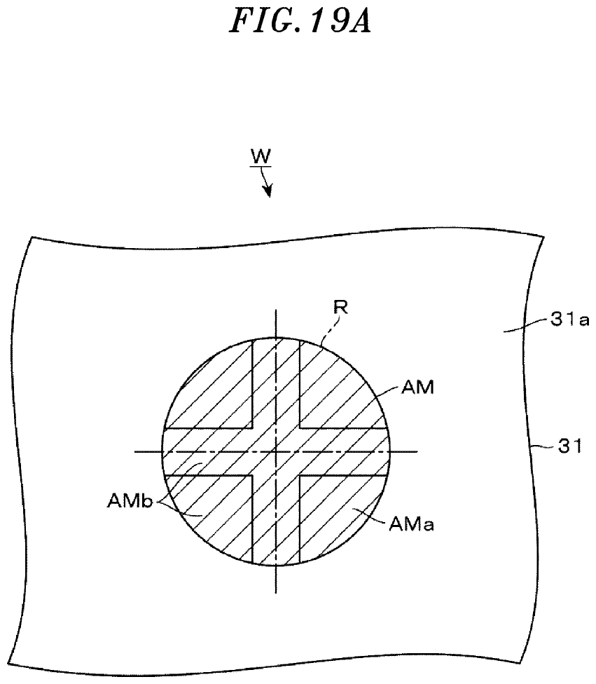

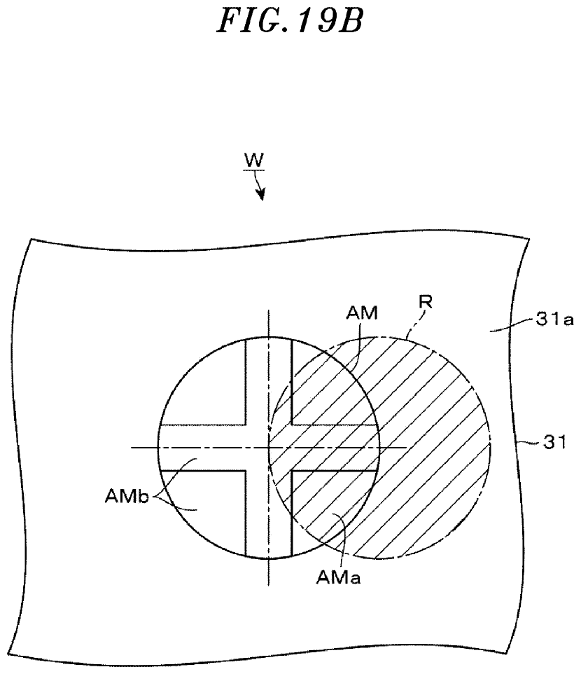

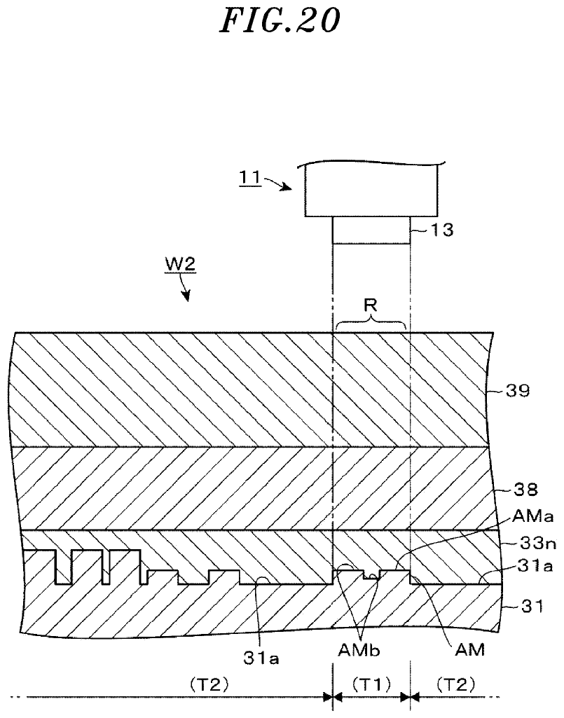

Hereinafter, the inspection apparatus 1 of the second embodiment will be described with reference to FIGS. 19A, 19B, and 20. The inspection apparatus 1 according to the second embodiment has a function of specifying the position of an alignment mark AM formed on a substrate W by utilizing a reflectance spectrum (characteristic spectrum) obtained by irradiating measurement light. FIG. 19A is a plan view showing a state in which the measurement area R is positioned at the alignment mark in the present embodiment. FIG. 19B is a plan view showing a state in which the measurement area R is deviated from the alignment mark in the present embodiment. In FIGS. 19A and 19B, the measurement area R is hatched, and the outer periphery of the measurement area R is indicated by a dash-dotted line. FIG. 20 is a longitudinal side view illustrating the positioning of the measurement area R with respect to the alignment mark on a substrate having a resist layer and a hard mask layer on a surface thereof.

The inspection apparatus 1 in the present embodiment uses spectroscopic measurement of the measurement part 11 to perform high-precision positioning of the measurement area R to the alignment mark AM as described in the comparative embodiment shown in FIG. 3. As shown in FIGS. 19A and 20, the alignment mark AM is, e.g., a convex portion formed on the surface of the underlying layer 31. The upper surface of the alignment mark AM constitutes a reference area AMa for indicating a reference position, and a characteristic uneven pattern AMb different from various uneven patterns of the substrate W is formed in the reference area AMa. Therefore, by utilizing the positioning method described in the first embodiment, the reflectance spectra for the reference area AMa on the upper surface of the underlying layer 31 and a peripheral area 31a thereof shown in FIGS. 19A and 19B are compared instead of the measurement positions II and III shown in FIGS. 4B and 4C. Hence, the measurement area R can be positioned at the alignment mark AM with high precision.

Here, the measurement area R in the present embodiment is set to have the same shape and the same area as those of the reference area AMa, for example. Therefore, the measurement area R is located in the reference area AMa without deviating from the reference area AMa when the center points of the measurement area R and the reference area AMa overlap in plan view, i.e., when the measurement area R is aligned with the reference area AMa. In the generation operation of the positioning, the reflectance spectrum in the case where the measurement area R is aligned is measured, used for training, and stored in the model data 122. In the determination operation, it is determined whether or not the measured reflectance spectrum matches the reflectance spectrum in the case where the measurement area R is aligned, which is obtained by the prediction model. When they do not match, the movement operation is performed, thereby positioning the center position of the measurement area R at the center of the alignment mark AM.

According to the determination operation of the present disclosure, it is possible to distinguish the reflectance spectrum in the case where the measurement area R is aligned as shown in FIG. 19A and the reflectance spectrum in the case where the measurement area R is deviated from the reference area AMa as shown in FIG. 19B. Therefore, according to the present embodiment, it is possible to determine a state in which the measurement area R is aligned with the alignment mark AM, thereby performing high-precision positioning.

In the substrate W shown in FIG. 20, a hard mask layer 38 that contains a metal to allow high-selectivity etching and lacks transparency, and a resist layer 39 may be provided on a surface film 33n to be etched. In this case, in the positioning performed by the image processing described in the comparative embodiment, the alignment mark AM cannot be recognized at the time of imaging, which makes the positioning extremely difficult. However, in the present embodiment, a light source that emits measurement light in an infrared wavelength range may be provided at the irradiator 14 to perform positioning utilizing spectroscopic measurement using infrared light that penetrates through the hard mask layer 38 and the resist layer 39, and such positioning can be used even for a substrate W having various layers.

The measurement area R may be set to have a shape that is similar to that of the reference area AMa and slightly smaller than that of the reference area AMa, as long as the positional deviation relative to the alignment mark AM is within an allowable range.

### Third Embodiment

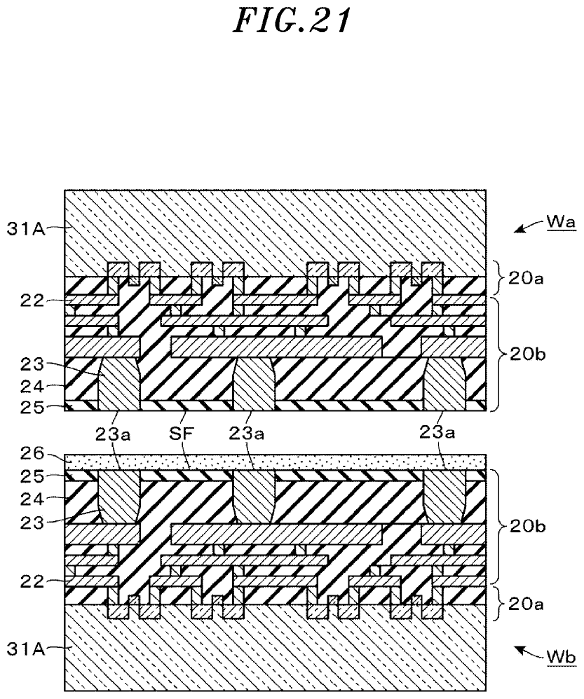

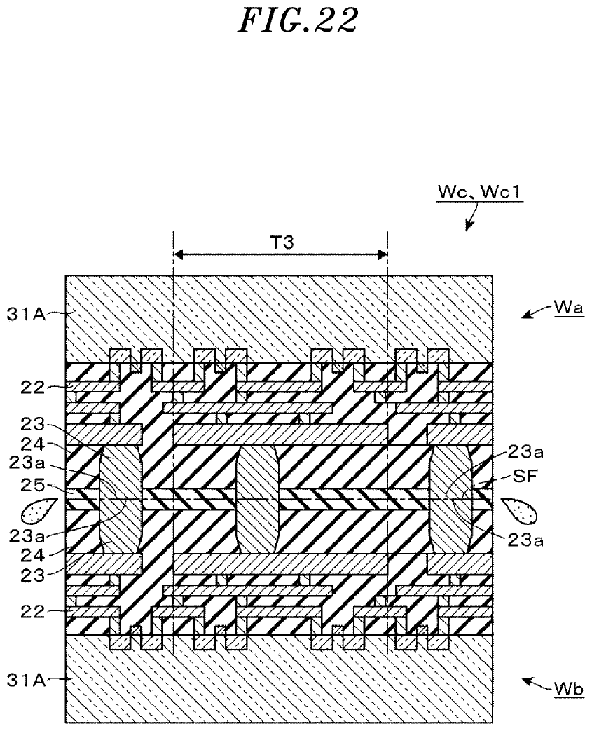

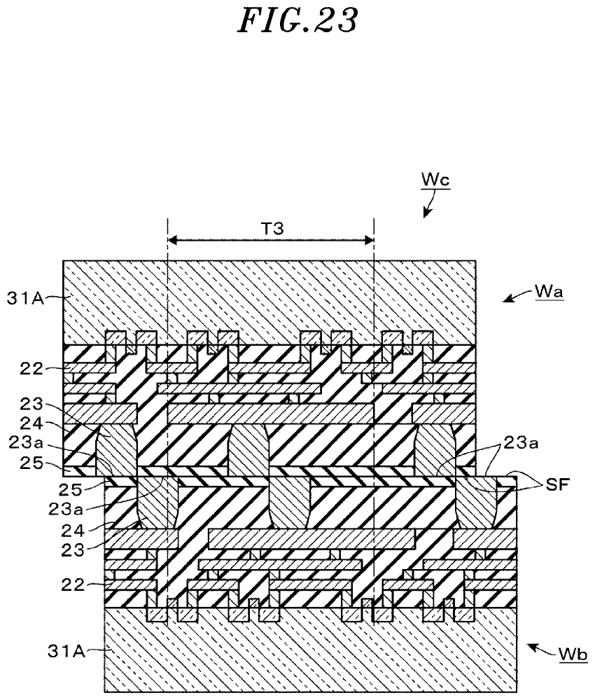

An inspection apparatus 1A of a third embodiment performs alignment inspection for inspecting whether or not a laminated substrate (bonded substrate) Wc formed by bonding the surfaces of an upper substrate Wa and a lower substrate Wb is aligned without positional deviation. Hereinafter, the substrate to be subjected to the alignment inspection will be described using FIGS. 21 to 23. FIG. 21 is a longitudinal side view of the upper substrate and lower substrate before bonding. FIG. 22 is a longitudinal side view showing the upper substrate and the lower substrate bonded in an aligned state. FIG. 23 is a longitudinal side view showing the upper substrate and the lower substrate bonded in a misaligned state.

First, the structure and bonding of the upper substrate Wa and the lower substrate Wb will be described with reference to FIG. 21. The upper substrate Wa and the lower substrate Wb have substantially the same configuration. Each of the upper substrate Wa and the lower substrate Wb has a base substrate 31A, a processing part 20a, and a wiring layer 20b. Hereinafter, the surface of the upper substrate Wa or the lower substrate Wb to which the other substrate Wa or Wb is bonded is referred to as “bonding surface SF.” The processing part 20a is formed to include a part of the base substrate 31A. The processing part 20a includes, e.g., a semiconductor device such as a transistor. The base substrate 31A is, e.g., a semiconductor wafer. The wiring layer 20b is, e.g., a multilayer wiring. The wiring layer 20b has a wiring 22, a metal pad 23, a first insulating film 24, and a second insulating film 25.

The wiring 22 is provided in multiple layers. The wiring 22 is electrically connected to the processing part 20a. The metal pad 23 is provided on the bonding surface SF side of the wiring 22 located farthest from the base substrate 31A. The metal pad 23 is electrically connected to the wiring 22. The metal pad 23 is electrically connected to the processing part 20a via the wiring 22. The surface of the metal pad 23 is exposed. The first insulating film 24 is, e.g., an interlayer insulating film filling the gap between the wirings 22.

The second insulating film 25 is provided on the bonding surface SF side of the first insulating film 24. The surface of the second insulating film 25 is exposed. The exposed surface of the second insulating film 25 is for example flush with the exposed surface of the metal pad 23. The second insulating film 25 is, e.g., an SiC film. Each of the upper substrate Wa and the lower substrate Wb has an area where the second insulating film 25 is exposed and an area where the metal pad 23 is exposed on the bonding surface SF. The second insulating film 25 is an example of an insulating film, and the metal pad 23 is an example of a conductive film.

The bonding of the upper substrate Wa and the lower substrate Wb will be described. First, the surfaces of the upper substrate Wa and the lower substrate Wb are flattened by chemical mechanical polishing (CMP) to form the bonding surfaces SF. An adhesive is applied to the bonding surfaces SF, thereby forming an adhesive film 26. As shown in FIG. 21, the upper substrate Wa is located on the upper side and the lower substrate Wb is located on the lower side of the upper substrate Wa, and they are positioned such that the exposed pad surfaces 23a of the metal pads 23 are not misaligned. Then, pressure is applied to bond the upper substrate Wa and the lower substrate Wb, thereby forming the laminated substrate Wc. As shown in FIG. 22, in the laminated substrate Wc, it is preferable that the upper substrate Wa and the lower substrate Wb are not misaligned in a direction parallel to the bonding surfaces SF, and the pad surfaces 23a of the metal pads 23 are aligned without deviation in a direction parallel to the bonding surfaces SF. Specifically, in the upper substrate Wa and the lower substrate Wb, it is preferable that a portion of the pad surface 23a of one metal pad 23 that is misaligned from and does not overlap the pad surface 23a of the other metal pad 23 is substantially zero.

However, as shown in FIG. 23, a case where the laminated substrate Wc is formed in a state where the bonding surfaces SF of the upper substrate Wa and the lower substrate Wb are misaligned and the pad surfaces 23a of the metal pads 23 are shifted from each other may occasionally occur during a manufacturing process. Therefore, according to the alignment inspection of the inspection apparatus 1A of the present embodiment, the laminated substrate Wc in a misaligned state can be detected with high precision and in a simple manner. Hereinafter, the alignment inspection of the present embodiment will be described based on the differences from the first embodiment.

The measurement part 11 (see FIG. 1) in the alignment inspection of the present embodiment irradiates infrared light, particularly infrared light in a wavelength range of 1000 nm or more, as measurement light in order to measure the internal structure of the laminated substrate Wc. The thicknesses of the laminated substrate Wc and the training laminated substrate Wc1 in the generation operation correspond to the film thicknesses of the surface films 33 of the substrate W and the training substrate W1 of the first embodiment. Thus, the singular point can be identified from the thicknesses of the laminated substrate Wc and the training laminated substrate Wc1.

In the present embodiment, in order to prevent noise from the stage 21, it is preferable to provide an infrared absorption sheet between the stage 21 and the substrate W. Alternatively, for example, instead of the coaxial structure of the coaxial probe 13, a probe connected to the irradiator 14 side and a probe connected to the measuring device 15 side may be provided separately, and a through-hole passing through the stage 21 in a vertical direction may be formed. The noise from the stage 21 can also be prevented by arranging the probe on the irradiator 14 side below the through-hole of the stage and arranging the probe on the measuring device 15 side above the through-hole and by receiving infrared light irradiated onto the substrate W. In this case, the positioning of the measurement area R in an inspection area T3 to be described later is performed by shifting the substrate W placed on the stage 21. The characteristic spectrum obtained when the measurement light passes through the substrate W may be, e.g., the intensity spectrum of the transmitted light that has passed through the substrate W and is received by the probe on the measuring instrument 15 side, or the absorption intensity spectrum, the absorbance spectrum, and the transmittance spectrum, which are the differences between the intensity spectrum of the irradiation light and the intensity spectra of the transmitted light and the reflected light. Since the transmitted light is the difference between the irradiation light irradiated to the measurement area R and the light reflected/absorbed by the substrate W, the intensity spectrum or the transmittance spectrum of the transmitted light reflects characteristics corresponding to reflection and absorption with respect to the wavelength of the measurement light. Therefore, the intensity spectrum or the transmittance spectrum of the transmitted light also correspond to the characteristic spectrum of the present disclosure.

In the alignment inspection, for example, the pad surfaces 23a of the laminated substrate Wc, the upper substrate Wa of the training laminated substrate Wc1, and the lower substrate Wb of the training laminated substrate Wc1 correspond to patterns such as the uneven pattern 32 described in the first embodiment and the modification thereof. According to the correlation, in the present embodiment, the alignment state or misalignment state of the metal pads 23 bonded together in the laminated substrate Wc and the training laminated substrate Wc1 appears as a change in the reflectance spectrum excluding singular points. Hence, the alignment state or misalignment state can be determined from the reflectance spectrum.

In the alignment inspection, for example, for the same inspection area T3 in the laminated substrate Wc and the training laminated substrate Wc1, the spectroscopic measurement is performed in the generation operation and the determination operation to measure the reflectance spectrum. The inspection area T3 is, e.g., a portion arbitrarily set to include the front and back surfaces of the laminated substrate Wc, and is a portion including an area where the pad surfaces 23a of the same pattern are arranged in the upper substrate Wa and the lower substrate Wb. In the generation operation, the singular points and the reflectance spectra measured for the inspection areas T3 of the training laminated substrates Wc1 with different thicknesses are stored as the training data 121 in the storage part 114. Then, the machine learning is performed on the training data 121 to generate a prediction model of the reflectance spectra correlated with the thicknesses of the training laminated substrates Wc1, and the prediction model is stored as the model data 122 in the storage part 114.

In the determination operation, the reflectance spectrum is measured for the inspection area T3 of the laminated substrate Wc to be inspected, and the measured reflectance spectrum is compared with the reflectance spectrum derived by inputting the thickness of the laminated substrate Wc into the prediction model to determine whether or not they match. From this result, it is determined whether the laminated substrate Wc is in an aligned state or in a misaligned state. As a result, it is possible to select the laminated substrate Wc determined to be aligned as a non-defective product, and the laminated substrate Wc determined to be misaligned as a defective product with high precision.

Further, in the alignment inspection, the reflectance spectrum in a misaligned state changes depending on multiple misalignment directions along the bonding surface SF and the misalignment amount (displacement amount) from the aligned state. Therefore, for example, in each misalignment direction in two orthogonal directions along the bonding surface SF, the misalignment amount can be varied within a preset range, and the reflectance spectra can be learned by the generation operation. In this case, by correlating the misalignment amount in each misalignment direction with the area information and relative position as in the modification of the first embodiment, the misalignment direction and misalignment amount of the laminated substrate Wc to be inspected can be estimated.

### (Bonding Apparatus 7D)

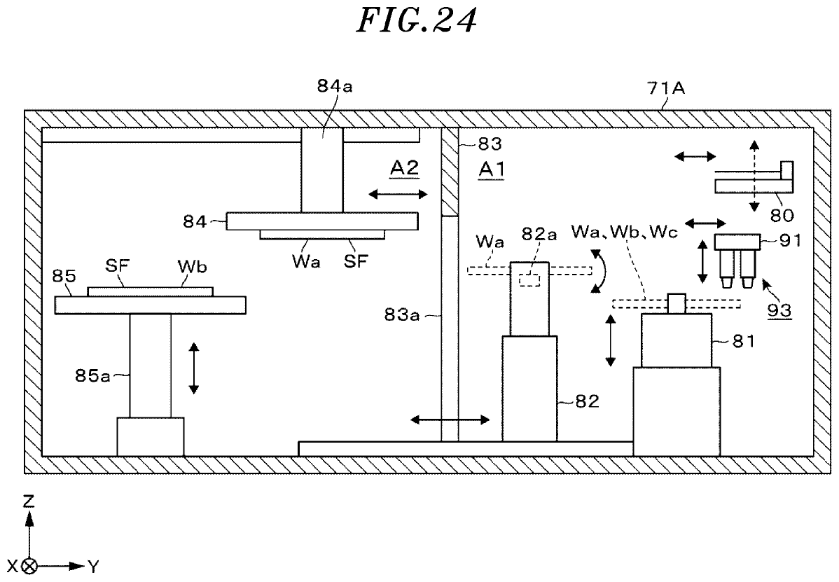

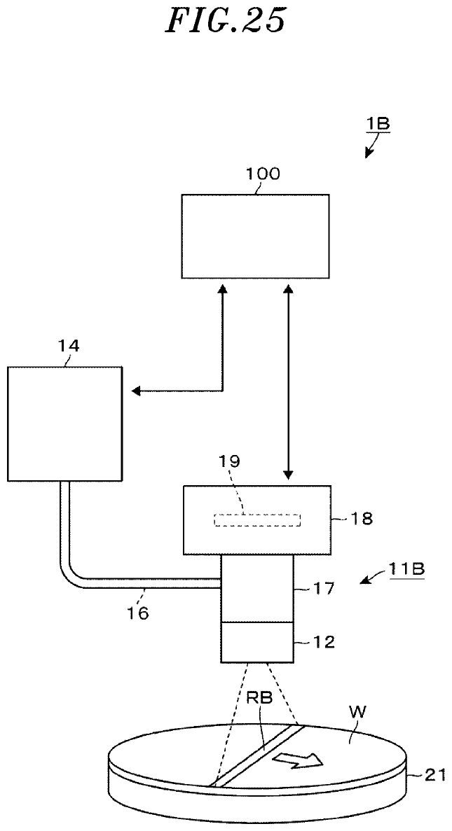

Hereinafter, a bonding apparatus 7D, which is installed together with the inspection apparatus 1A of the present embodiment and configured to bond the upper substrate Wa and the lower substrate Wb, will be briefly described. FIG. 24 is a longitudinal side view showing the bonding apparatus 7D. In the bonding apparatus 7D, the upper substrate Wa is loaded through a substrate loading/unloading port (not shown) formed in a processing chamber 71A on a transfer area A1 side. Next, the upper substrate Wa is transferred to a position adjustment mechanism 81 by a substrate transfer body 80 that is movable in the Y and Z directions. The position adjustment mechanism 81 is configured to rotate each of the held substrates Wa to Wc around their respective centers to adjust the horizontal position of each of the substrates Wa to Wc. After the position of the upper substrate Wa loaded first is adjusted by the position adjustment mechanism 81, the upper substrate Wa is transferred to a holding arm 82a of an inversion mechanism 82 with the bonding surface SF facing upward.

The inversion mechanism 82 inverts the front and back surfaces of the held upper substrate Wa by inverting the holding arm 82a in the transfer area A1, so that the bonding surface SF of the upper substrate Wa faces downward. Then, the inversion mechanism 82 passes through a loading/unloading port 83a provided in a partition wall 83 that partitions the transfer area A1 and a processing area A2, and moves to an upper chuck 84 side of the processing area A2. The upper chuck 84 holds the upper substrate Wa by attracting the back surface of the upper substrate Wa. Next, the upper chuck 84 is moved to an opposing position above the lower chuck 85 by a chuck driving part 84a that is movable in the Y direction. The upper substrate Wa stands by until the lower substrate Wb is transferred to the bonding apparatus 7D.

Next, the lower substrate Wb is loaded into the bonding apparatus 7D, and the lower substrate Wb is transferred to the position adjustment mechanism 81 by the substrate transfer body 80. Then, a nozzle arm 91, which is movable in the Y and Z directions and has a nozzle 93 attached thereto, moves the nozzle 93 to a position above the center of the lower substrate Wb. Next, the position adjustment mechanism 81 rotates the lower substrate Wb, applies an adhesive to the surface of the lower substrate Wb by spin coating using an adhesive supply mechanism connected to the nozzle 93, and adjusts the horizontal orientation of the lower substrate Wb.

Next, the lower substrate Wb is transferred to the lower chuck 85 in the processing area A2 by the substrate transfer body 80, and the back surface of the lower substrate Wb is attracted and held by the lower chuck 85 with the bonding surface SF facing upward. Next, the horizontal position adjustment of the lower substrate Wb held by the lower chuck 85 and the upper substrate Wa held by the upper chuck 84 is performed while capturing images of the bonding surfaces SF with a CCD camera, for example. Specifically, based on the captured images, the horizontal position of the upper substrate Wa is adjusted by the upper chuck 84 such that a predetermined reference point (not shown) on the surface of the lower substrate Wb matches a reference point (not shown) on the surface of the upper substrate Wa (see FIG. 21).

Next, the lower chuck 85 is raised by a chuck driving part 85a configured to raise and lower the lower chuck 85, and the lower substrate Wb held by the lower chuck 85 and the upper substrate Wa held by the upper chuck 84 are press-bonded with the respective bonding surfaces SF brought into contact with each other (see FIGS. 22 and 23). Accordingly, the upper substrate Wa and the lower substrate Wb are bonded by the adhesive, thereby forming the laminated substrate Wc. The formed laminated substrate Wc is unloaded from the bonding apparatus 7D in the reverse order to the order in which any one of the upper substrate Wa and the lower substrate Wb was loaded into the processing area A2, and loaded into the inspection apparatus 1A.

The inspection apparatus 1A performs alignment inspection using the loaded laminated substrate Wc as a substrate to be inspected, and determines whether it is in an aligned state or a misaligned state. As described above, according to the determination operation of the present disclosure, a defective laminated substrate Wc determined to be in a misaligned state can be detected with high precision and in a simple manner.

### Fourth Embodiment

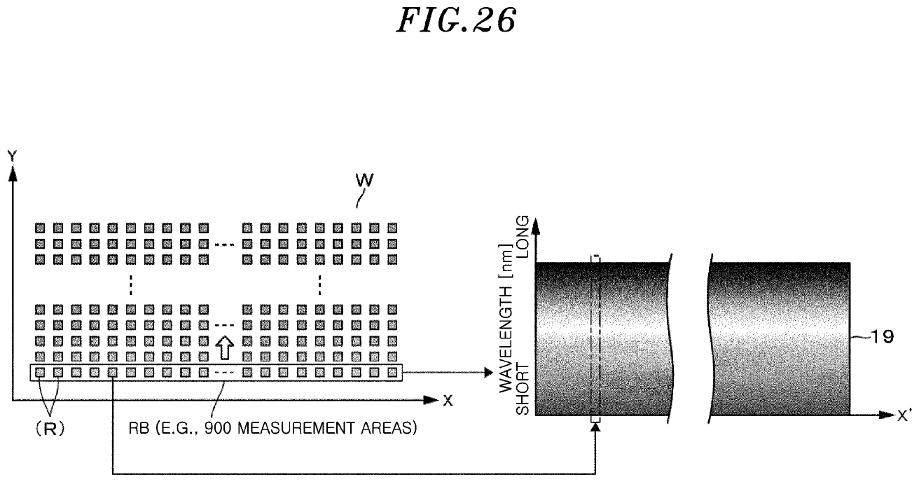

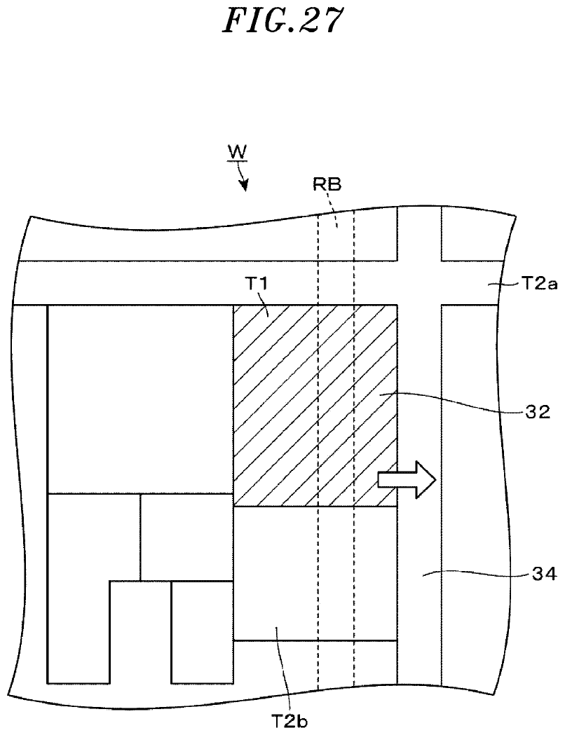

An inspection apparatus 1B of the fourth embodiment will be described with reference to FIGS. 25 to 31. In FIGS. 25 to 31, the same reference numerals will be used for structures similar to those in the first embodiment to omit redundant description thereof, and the differences from the first embodiment will be mainly described. FIG. 25 is a structural diagram showing the inspection apparatus 1B according to the fourth embodiment. FIG. 26 is an explanatory diagram showing the principle of spectroscopic measurement by a hyperspectral camera (hereinafter, referred to as “HSC”) 11B constituting the inspection apparatus 1B.

As shown in FIGS. 25 and 26, the HSC 11B includes a lens 12, a spectrometer 17, and a camera 18. In the fourth embodiment, the HSC 11B is configured to perform spectroscopic measurement by arranging 900 optical elements side by side, for example. In other words, an elongated rectangular measurement area RB is formed by arranging multiple measurement areas R in the inspection apparatus 1 described with reference to FIG. 1 side by side. By scanning the substrate W while moving the measurement area RB, the spectroscopic measurement of the entire surface of the substrate W can be performed efficiently. Specifically, in the HSC 11B, incident light from the elongated rectangular measurement area RB, which has entered through the lens 12, is introduced into the spectrometer 17 through a horizontally elongated slit (not shown), is dispersed, and then received by an area sensor 19 provided in the camera 18.

As shown in FIG. 26, in the area sensor 19, 900 optical elements are arranged in a row in the X′ direction (horizontal direction), similarly to the above-described measurement area RB. There are multiple rows of the optical elements arranged in a vertical direction intersecting the above-described horizontal direction within the area irradiated with the light dispersed by the spectrometer 17. With this configuration, the area sensor 19 receives, in a matrix form, light of each wavelength after dispersion in each area (measurement area R) obtained by dividing the horizontal width X of the measurement area RB into 900 portions, for example, using the optical elements arranged in the area of the vertical width Y. With the HSC 11B of such a configuration, the above-described characteristic spectrum can be constructed based on results of measuring, for each wavelength, the intensity of light received by the light-receiving elements at multiple positions (900 positions in this example) in the horizontal direction of the measurement area RB in a single scan. Further, by scanning the measurement area RB in a direction (e.g., the Y direction) intersecting the longitudinal direction of the measurement area RB (corresponding to the above-described “horizontal direction”) and performing spectroscopic measurement at minute intervals, the HSC 11B can perform spectroscopic measurement on the surface of the substrate W divided into a high-density matrix form.

A data set including multiple reflectance spectra acquired in a single scan has a data size on the order of terabytes, for example, and is stored in a memory (not shown) in the control device 100. The data set is used for each process of positioning and film thickness inspection by the individual components of the control part 115. The above-described data set acquisition operation is repeated in subsequent scans as well.

Since the HSC 11B performs spectroscopic measurement simultaneously at the respective horizontal positions of the measurement area RB in a single scan, there is no illumination change due to differences in measurement timing. Further, since the illuminance is substantially the same at multiple positions adjacent in the X direction in the measurement area RB in a single scan, the illuminance of light incident on the optical elements at the corresponding multiple positions is substantially the same. Since the upper surface of the substrate W can be scanned in a short period of time and the spectroscopic measurement can be performed in a high-density matrix form, it is considered that there is substantially no illuminance difference in the spectroscopic measurements at multiple positions adjacent in the Y direction in addition to the X direction. Therefore, for each area composed of multiple positions adjacent in the X and Y directions where there is substantially no illumination difference on the surface of the substrate W on which the spectroscopic measurement is performed in a high-density matrix form, it is not necessary to consider the influence of the illuminance difference of the light irradiated onto the substrate W on the reflectance spectrum.

FIG. 27 is a partial plan view showing the measurement area RB where the spectroscopic measurement in the fourth embodiment is performed. FIG. 28 is a graph illustrating characteristic spectra in the areas T1, T2a, and T2b shown in FIG. 27, where the vertical axis represents an absorption intensity spectrum, which is the difference between the intensity of irradiation light and the intensity of reflected light among various characteristic spectra described above. It is assumed that surface films 33 having the same thickness are formed in the areas T1, T2a, and T2b. In this example, the scan is performed while moving the measurement area RB on the substrate W. For the absorption intensity spectrum measured in the measurement area RB shown in FIG. 27, multiple absorption intensity spectra slightly shifted from each other at the respective measurement positions in the width direction of the measurement area RB are measured. Therefore, when the absorption intensity spectra obtained by scanning the areas T1, T2a, and T2b using the measurement area RB are superimposed, they form a characteristic spectrum group (absorbance intensity spectrum group) including an area having a width in the intensity (light amount) value (see FIG. 28), rather than a single linear characteristic spectrum having no width in the reflectance value of FIG. 5. However, even in an absorbance intensity spectrum group with different intensity values, at the wavelength where the spectra of the areas T1, T2a, and T2b intersect, the intensity values converge substantially to one point, and the above-described singular points P7 and P8 appear. Even when other characteristic spectra described in the first or third embodiment are measured, a characteristic spectrum group having a width or singular points are obtained.

Therefore, according to the spectroscopic measurement of the fourth embodiment, the positioning of the present disclosure can be implemented by the same manner as that of the first embodiment. For example, based on the flowchart described with reference to FIG. 9, it is determined whether the measurement area RB is located in the inspection area T1, or in the non-inspection area T2b, or in the boundary between the inspection area T1 and the non-inspection area T2b. In this case, even if the scanning is performed in a state where the measurement area RB shown in FIG. 27 is fixed without being moved, multiple reflectance spectrum groups (e.g., for 900 light receiving elements, i.e., 900 pixels) can be acquired in the measurement of step S205 in FIG. 9 as described above. Accordingly, in a subsequent step S206 of FIG. 9, it is determined whether or not the reflectance spectrum groups include a reflection spectrum having singular points that match the singular points by the prediction model. When the reflectance spectrum having singular points that match the singular points by the prediction model is included (step S206: Yes), it is determined whether or not this reflectance spectrum matches the reflectance spectrum of the inspection area derived from the prediction model (step S207). When the reflectance spectra do not match (step S207: No), the measurement area RB is moved (step S208), and the operations of steps S205 to S207 are repeated.

As described above, in the case of using the HSC 11B capable of performing spectroscopic measurement on multiple points in a short period of time, it is not necessary to determine the arrangement state of the substrate W based on the flowchart of FIG. 9. For example, regarding a reflectance spectrum group obtained by scanning the entire surface of the substrate W while moving the measurement area RB, whether a reflectance spectrum that has singular points that match the singular points of the prediction model and that matches the reflectance spectrum of the inspection area T1 by the prediction model is included or not may be determined collectively. When there is a spectrum that has singular points that match the singular points by the prediction model and that matches the reflectance spectrum by the prediction model, the position on the surface of the substrate W where this reflectance spectrum was acquired is identified. The acquisition position of the reflectance spectrum may be identified based on, e.g., the arrangement position of the measurement area RB where the reflectance spectrum was acquired during the scan and the position of the pixel (optical element) in the measurement area RB.

As will be described in detail in the following examples, according to the positioning and the film thickness inspection of the present disclosure, particularly in the fourth embodiment, the identification of the singular point and the reflectance spectrum are less susceptible to influence from defocusing blur or illuminance changes. Therefore, even when it is applied to in-line inspection incorporated in a processing module where disturbances such as vibration or illuminance variation are frequently expected to cause defocusing or illuminance changes, the positioning or the like can be performed with minimal influence from such disturbances.

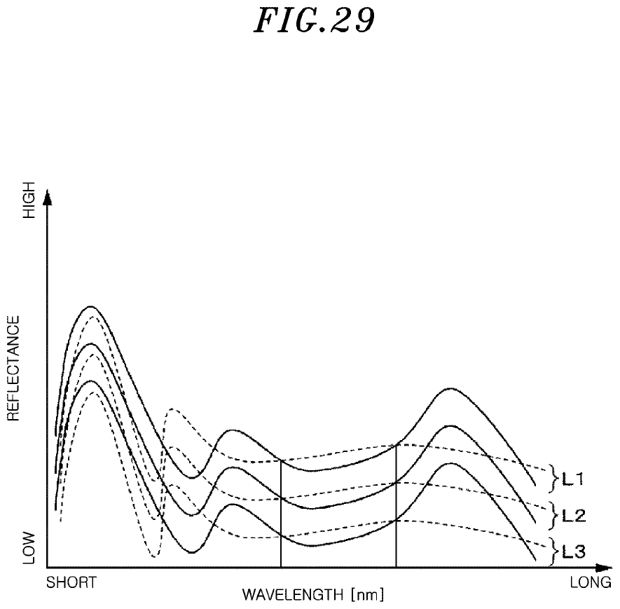

The illuminance fluctuation, which is an example of the disturbances, will be described. FIG. 29 is a graph illustrating reflectance spectra obtained when the measurement area RB is located across two adjacent areas (e.g., the areas T1 and T2b in FIG. 27) having the same film thickness and different patterns, and spectroscopic measurement is performed under different illuminances L1 to L3. In FIG. 29, the solid line indicates a representative reflectance spectrum for one of the areas T1 and T2b, and the dashed line indicates a representative reflectance spectrum for the other area. As described above, according to the spectroscopic measurement of the fourth embodiment, in a single scan of spectroscopic analysis, the illuminance at multiple positions that are continuous in the horizontal direction in the measurement area RB may be considered substantially the same. Hence, according to the reflectance spectra in the respective adjacent areas measured in a single scan, the spectroscopic measurement is performed with substantially the same illuminance.

During repeated scanning of multiple substrates W, the illuminance of the irradiation light may change due to, e.g., contamination of the window through which the irradiation light or the reflected light passes. In this regard, FIG. 29 shows that even when reflectance spectra are acquired under different illuminances L1 to L3, the wavelength of the singular point where the reflectance spectra acquired from the areas T1 and T2b with different pattern shapes intersect does not change. Therefore, according to the spectroscopic measurement of the fourth embodiment, even when illuminance fluctuation expected in the in-line inspection occurs, the arrangement state of the substrate W can be stably identified based on the wavelength of the singular point, which is less susceptible to the illuminance variation. An example of the in-line inspection using a film forming module 7E equipped with the inspection apparatus 1B will be described in the following modification.

### Application Example of Fourth Embodiment

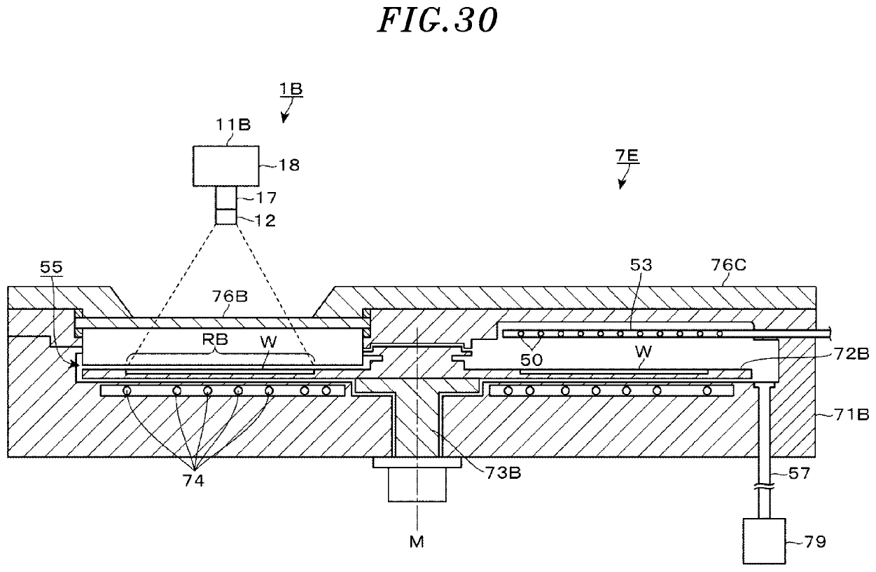

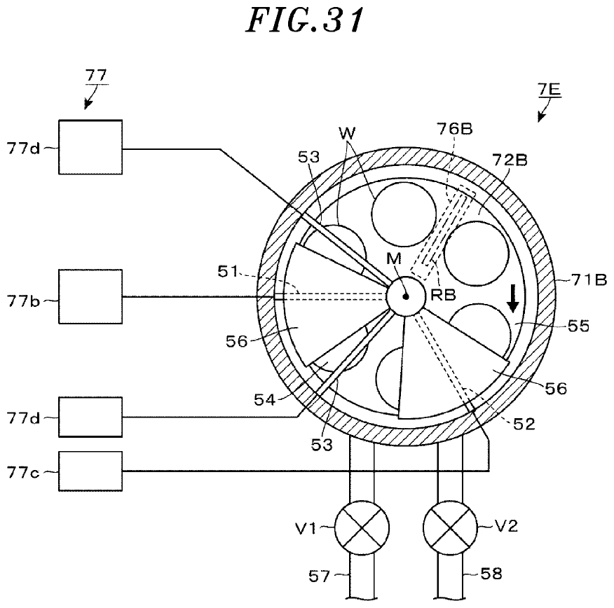

In the application example of the fourth embodiment, a case where the inspection apparatus 1B is attached to a semi-batch type film forming module 7E (substrate processing apparatus) provided instead of the third processing module 7C where film formation is performed, and in-line inspection is performed immediately after film formation in the film forming module 7E will be described. FIGS. 30 and 31 are a longitudinal side view and a horizontal plan view showing the semi-batch type film forming module 7E, respectively. As shown in FIGS. 30 and 31, the processing chamber 71B is, e.g., a flat cylindrical vacuum container in which a horizontal rotary table (table) 72B serving as a placing table is provided. The rotary table 72B rotates around a central axis (rotation axis) M by a rotation mechanism 73B provided at the center of the rotary table 72B. A plurality of substrates W are placed on the rotary table 72B, and the substrates W revolve around the central axis M as the rotary table 72B rotates.

As shown in FIG. 31, a raw material gas nozzle 51 for supplying a raw material gas and a reaction gas nozzle 52 for supplying a reaction gas are provided in an area through which the substrate W passes during revolution. Purge gas nozzles 53 for supplying a purge gas are provided in two areas between the raw material gas nozzle 51 and the reaction gas nozzle 52. The raw material gas nozzle 51, the reaction gas nozzle 52, and the purge gas nozzle 53 are spaced apart from each other in the circumferential direction and extend horizontally from the sidewall of the processing chamber 71B toward the center of the processing chamber 71B. The raw material gas nozzle 51, the reaction gas nozzle 52, and the purge gas nozzle 53 are provided with multiple gas injection holes 50 (see FIG. 30) for injecting various supplied gases into the processing chamber 71B along the longitudinal direction.

As shown in FIG. 31, by arranging partition members 56 in two areas surrounded by the two purge gas nozzles 53, the space in the processing chamber 71B is partitioned into a raw material gas supply area 54 and a reaction gas supply area 55, for example. Accordingly, the mixing of the raw material gas and the reaction gas in the processing chamber 71B is suppressed. Further, the raw material gas supply area 54 and the reaction gas supply area 55 are connected to the exhaust device 79 (see FIG. 30) through exhaust lines 57 and 58 respectively provided with valves V1 and V2.

The gas supply part 77 (processing gas supply part) includes a raw material gas supply system 77b, a reaction gas supply system 77c, and a purge gas supply system 77d formed of independent supply lines and having respective gas supply sources. The raw material gas supply system 77b, the reaction gas supply system 77c, and the purge gas supply system 77d are provided with flow rate controllers such as valves or mass flow controllers, and are connected to the raw material gas nozzle 51, the reaction gas nozzle 52, and the purge gas nozzle 53, respectively. Hence, the raw material gas, the reaction gas, and the purge gas are continuously supplied from the respective supply sources to the raw material gas nozzle 51, the reaction gas nozzle 52, and the purge gas nozzle 53.

In the film forming module 7E, as the rotary table 72B rotates, the substrate W passes through the raw material gas supply area 54 and, thus, the raw material gas is adsorbed on the wafer surface. Next, as the substrate W passes through the reaction gas supply area 55, the raw material gas on the wafer surface reacts with the reaction gas, thereby forming a film. As described above, as the substrate W alternately passes through the raw material gas supply area 54 and the reaction gas supply area 55, the surface film 33 is formed on the substrate W by the ALD method, similarly to the first embodiment.

In the processing chamber 71B, an area above the area 55 to which the reaction gas is supplied is partially opened, and the opening is closed by a window 76B that transmits light for the above-described spectroscopic measurement. In order to maintain the airtightness of the processing chamber 71B, the peripheral portion of the window 76B is sandwiched via an O-ring between the processing chamber 71B and an upper cover 76C attached to the upper part of the processing chamber 71B. The upper cover 76C has an upper opening at the central portion thereof so as not to block the central area of the window 76B that transmits light.

The HSC 11B is located above the window 76B, and is configured to receive light reflected from the measurement area RB through the central area of the window 76B. The HSC 11B is installed with the lens 12 toward the measurement area RB such that the measurement area RB is located within a range that covers the diameter of the revolving substrate W (see FIG. 36). In the HSC 11B, the orientation of the lens 12 is adjusted such that the measurement area RB extends radially from the sidewall of the processing chamber 71B toward the center of the processing chamber 71B, i.e., toward the central axis M in plan view, similarly to the nozzles 51 to 53.

Each substrate W after the formation of the surface film 33 is scanned by the HSC 11B while revolving in the film forming module 7E. In other words, each revolving substrate W enters the area below the measurement area RB and, then, the entire surface thereof passes through the area below the measurement area RB. The HSC 11B can measure the reflectance spectrum over the entire upper surface of the substrate W by performing spectroscopic measurement at minute intervals for the measurement area RB that moves as described above. According to the in-line inspection in the film forming module 7E, the measurement area RB can be efficiently and accurately positioned in the inspection area T1, and the film thickness inspection can be performed.

Conventionally, in the in-line inspection in the film forming module 7E, it was difficult to utilize the high-precision spectroscopic measurement performed by the HSC 11B due to various disturbances. The disturbances may include, e.g., temporal changes in illuminance caused by clouding of the window 76B due to various gases supplied during film formation, and diagnostic failure resulting from image blurring. In addition, the disturbances may include the inclination of the rotary table 72B from a center side toward an outer side, and defocusing caused by rotational vibration of the rotary table 72B. According to the conventional spectroscopic measurement using the HSC 11B, it was difficult to obtain accurate measurement results under such disturbances. In contrast, by performing determination based on the reflectance spectrum and the singular points thereof as in the present disclosure, the positioning and the film thickness inspection can be performed accurately and efficiently without being affected by the disturbances, as will be described in the following examples.

### Other Modifications

The HSC 11B of the fourth embodiment does not necessarily perform scanning at minute intervals while moving the linear measurement area RB. For example, the HSC 11B may be of another type in which spectroscopic measurement is performed by changing multiple spectroscopic filters corresponding to different bands in a state where the area-shaped measurement area RB is fixed. Alternatively, instead of the HSC 11B, multiple measurement parts 11 used in the first embodiment may be provided. By integrally moving the respective coaxial probes 13, the spectroscopic measurement may be performed at the same timing while integrally moving the measurement areas R, similarly to the measurement areas RB.

The inspection apparatus 1B is not limited to the film forming module 7E, and may be attached to another processing module. Alternatively, the inspection apparatus 1B may be located as a standalone inspection apparatus in the film forming system 10 as in the first embodiment without being attached to the processing module. In this case, the stage is not limited to a rotary stage, and the spectroscopic measurement may be performed while moving the substrate placed on a rail-shaped stage that moves in one direction. Alternatively, the substrate may be maintained stationary, and the measurement area RB may be relatively moved by moving the HSC 11B.

### Examples

### (Test 1)

In order to confirm the effectiveness of the alignment inspection of the third embodiment, unbonded wafers were superimposed with an extremely small amount of misalignment, and the reflectance spectrum of a predetermined inspection area was measured.

### A. Test Conditions

Two test element group (TEG) wafers having the same L/S pattern on surface layers with a thickness of 350 nm were prepared. The wafers have a thickness of 775 μm at portions where the L/S patterns are not included. At such portions, metals such as the metal pads 23 are embedded in an uneven pattern of silicon oxide (SiO₂), silicon nitride (SiN), or the like, which has a small effect on the absorption and reflection of infrared light. The wafers were superimposed in an unbonded state such that both surface layers faced upward, without misalignment of the L/S patterns, and placed on a flat stage. Then, a test was conducted five times (Tests 1 to 5) in which a small vibration was applied to the stage to give an extremely small amount of misalignment between the wafers, to the extent that quantitative measurement was difficult, and the reflectance spectrum was measured. In each test, the measurement was performed five times, and it was confirmed that there was no change in all five reflectance spectra.

### B. Test Results

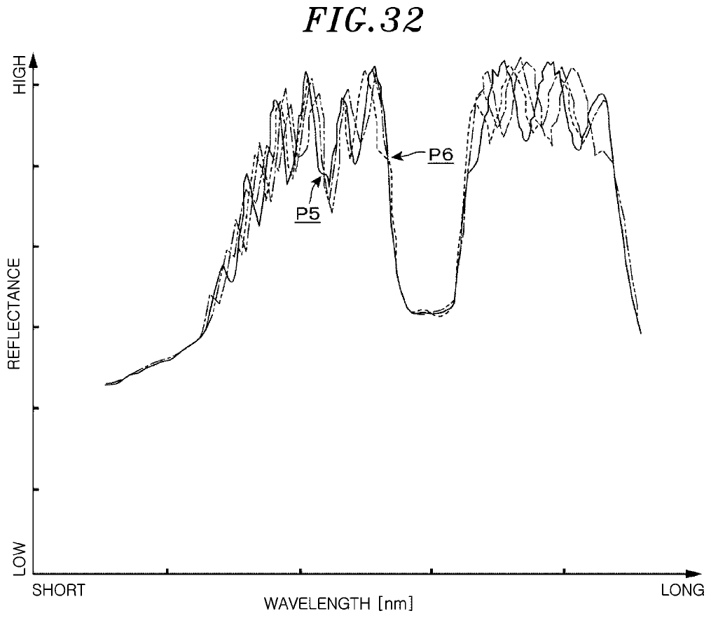

FIG. 32 shows the reflectance spectra representing the results of Test 1. In FIG. 32, different line types are used for different reflectance spectra of Tests 1 to 5. Since, however, some reflectance spectra overlap, they are indicated by solid lines, dashed lines, dash-dotted lines, and dashed double-dotted lines.

As shown in FIG. 32, no changes were observed in the five measurements for the respective reflectance spectra of Tests 1 to 5. This confirms that the reflectance spectrum corresponds to the misalignment direction and the misalignment amount, and that the misalignment direction and the misalignment amount can be estimated from the reflectance spectrum measured for the laminated substrate Wc to be inspected using a prediction model. In FIG. 32, singular points P4 and P5 where the five reflectance spectra intersect appeared, and it was confirmed that the wavelength of the singular point P4 corresponds to the wavelength corresponding to the thickness of the wafer. Accordingly, it was confirmed that the singular points also have the above-described characteristics. Hence, it was confirmed that according to the alignment inspection of the third embodiment, even extremely minute misalignment of the laminated substrate Wc can be detected easily and accurately.

### (Test 2)

Under conditions where defocusing and illuminance differences expected in the above-described in-line inspections occur, the trends of the singular points and the reflectance spectra identified by the spectroscopic measurement of the fourth embodiment were confirmed.

### A. Test Conditions

As a substrate W to be tested, a bare wafer having multiple sets of test patterns formed on its surface was prepared. In each set of test patterns, two different pattern areas were provided to identify a singular point for each set, and a SiN film having the same thickness was formed thereon. In order to identify singular points corresponding to the film thickness, different thicknesses were used for different sets. Then, the entire upper surface of the substrate W was scanned to perform spectroscopic measurement on the two pattern areas of each set of test patterns, and the reflectance spectra of the two different pattern areas were acquired for each set. From their intersection points, singular points corresponding to the film thickness of each set of test patterns were confirmed.

In order to reproduce an environment with defocusing or illuminance differences, the height of the lens 12 was adjusted so that the spectroscopic measurements were performed under a low-resolution condition in which the width of the measurement area RB on the substrate W was relatively large, and a high-resolution condition in which the width was relatively small and the resolution was approximately 110 times higher than the low resolution. The high-resolution condition reproduced a relatively high illuminance and an in-focus state, whereas the low-resolution condition reproduced a relatively low illuminance and an out-of-focus state.

Further, for the reflectance spectra of each data set acquired through the high- and low-resolution scans, data sets converted into absolute reflectance values were also prepared to cancel out illuminance differences. FIG. 33 is a table summarizing the aforementioned spectroscopic measurement conditions <1> to <5>. The data sets for the conditions <1> to <5> were prepared to confirm the trends of the singular points identified under the conditions <1> to <5>. In FIG. 33, the singular point wavelengths measured under the conditions <1> to <4> for a certain test pattern among the multiple sets are also listed. The condition <5> is based on the spectroscopic measurement in the first embodiment using a single measurement area R.

Then, it was checked whether the singular point wavelengths identified by the measurement of each set of test patterns under the conditions <1> to <5> correspond to the film thicknesses of each set of test patterns. As an additional test, singular points in a test pattern provided with relatively large voids were checked by the low-resolution spectroscopic measurement.

### B. Test Results

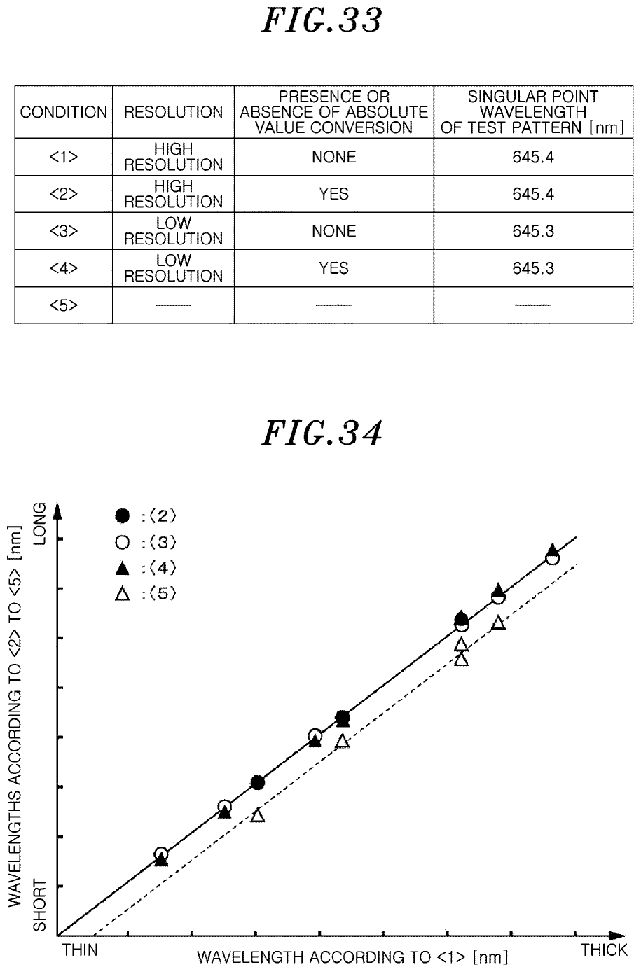

FIG. 34 is a graph showing the singular point wavelengths that are the results of Test 2. FIG. 34 plots the singular point wavelengths of each set of test patterns for each condition. The horizontal axis represents the singular point wavelength (nm) obtained from the reflectance spectrum under the condition <1> (high resolution, no absolute value conversion), and the vertical axis represents the singular point wavelength (nm) obtained from the reflectance spectrum under the conditions <2> through <5>. In other words, FIG. 34 plots the singular point wavelengths (vertical axis) of the respective sets of test patterns measured under the conditions <2> to <5> with respect to the singular point wavelengths (horizontal axis) of the same sets of test patterns measured under the condition <1>.

As shown in FIG. 34, the plots of the singular point wavelengths under the condition <1> and the singular point wavelengths under the conditions <2> to <4> overlapped on a straight line with a slope of 1. As indicated by these plots, it was confirmed that the singular point wavelengths measured under the conditions <1> to <4> were the same according to the film thickness of each set of the test patterns, and no substantial difference was observed regardless of whether the measurement was performed at a low resolution or at a high resolution and regardless of whether the conversion to absolute reflectance was performed or not. Therefore, it was confirmed that according to the spectroscopic measurement of the fourth embodiment, the positioning or the like can be performed based on the reflectance spectrum using the singular points of the present disclosure, without being affected by variation in the focal length of the lens 12 or the illuminance. Further, it was confirmed that accurate singular points can be identified from the reflectance spectrum that is the measured relative value without performing conversion to absolute reflectance to cancel out illuminance differences.

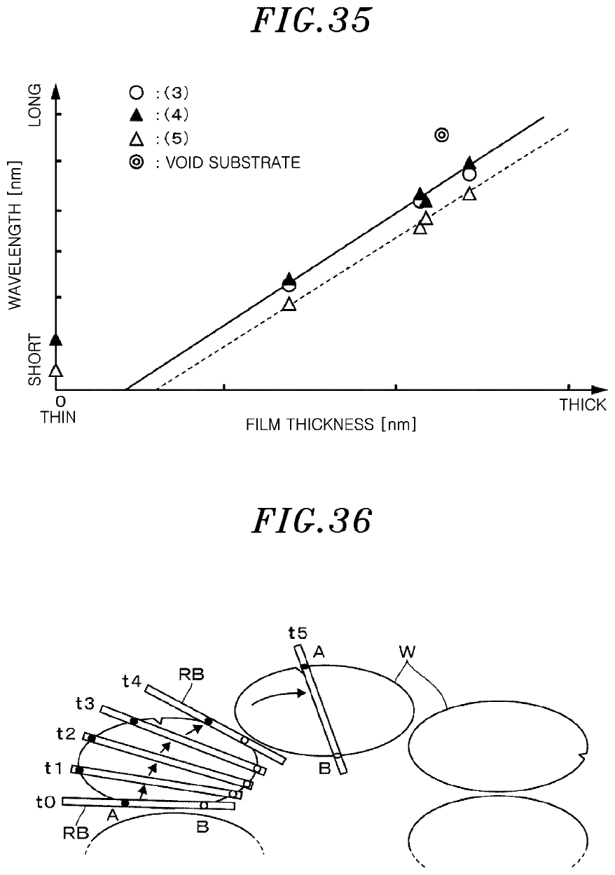

In addition, it was confirmed that the respective singular point wavelengths under the conditions <1> to <4> shown in FIG. 34 matched the singular point wavelengths corresponding to the respective film thicknesses. FIG. 35 shows the correlation between some of the singular point wavelengths identified under the conditions <3> to <5> and the film thickness. As shown in FIG. 35, the singular point wavelengths under the conditions <3> and <4> are proportional to the film thickness as described in the first embodiment, and it was confirmed that the correlation also exists between the film thickness and the singular points in the spectroscopic measurement of the fourth embodiment.

In a pattern area where the film thickness is 0 nm, i.e., where no SiN film is provided, a singular point appears, but its wavelength deviates from the proportional relationship with the film thickness observed in other singular point wavelengths corresponding to film thicknesses of 0 nm or more. Further, as shown in FIGS. 34 and 35, the singular point wavelengths under the condition <5> by the spectroscopic measurement of the first embodiment are about 5 nm shorter than the singular point wavelengths under the conditions <1> to <4> by the spectroscopic measurement of the fourth embodiment, including the film thickness of 0 nm. This is considered to be due to a calibration-specific deviation of the spectrometer used under the condition <5>. Therefore, if this deviation is identified in advance and corrected, it is inferred that the spectroscopic measurement of the first embodiment can achieve a level of accuracy similar to that of the fourth embodiment.

FIG. 35 shows, as an additional test result, singular points identified by the spectroscopic measurement of the fourth embodiment for another test pattern where a SiN film having voids was formed. A singular point appeared at a wavelength that deviates from the singular point wavelength corresponding to that film thickness. Thus, it was confirmed that even with the low-resolution spectroscopic measurement of the fourth embodiment, accurate singular points appear, and SiN films containing voids can be identified. Further, it was inferred that under the low-resolution condition capable of performing spectroscopic measurement over a wide range in a single scan, reflectance spectra of different pattern areas are likely to be found within a single scan, thereby allowing rapid identification of singular points.

### (Test 3)

In performing positioning and film thickness inspection using spectroscopic measurement by the HSC 11B in the film forming module 7E as shown in the modification of the fourth embodiment, it is confirmed whether the positions on the substrate W can be detected for multiple reflectance spectra included in each data set.

### A. Test Conditions

FIG. 36 is a top perspective view of multiple substrates W to be subjected to spectroscopic measurement in Test 3. In Test 3, the spectroscopic measurement of multiple substrates W placed and revolving on the rotary table 72B in the film forming module 7E was reproduced as shown in the modification of the fourth embodiment. Regarding the measurement area RB, the position of the lens 12 was set under low-resolution conditions such that its horizontal width X becomes longer than the diameter of the substrate W. Then, while moving the measurement area RB in a revolving manner extending toward the central axis M relative to the multiple substrates W, the spectroscopic measurement was performed at minute intervals to obtain multiple data sets.

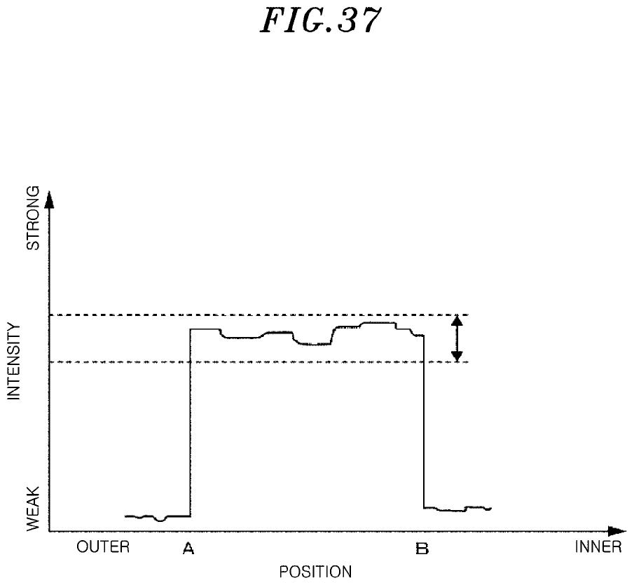

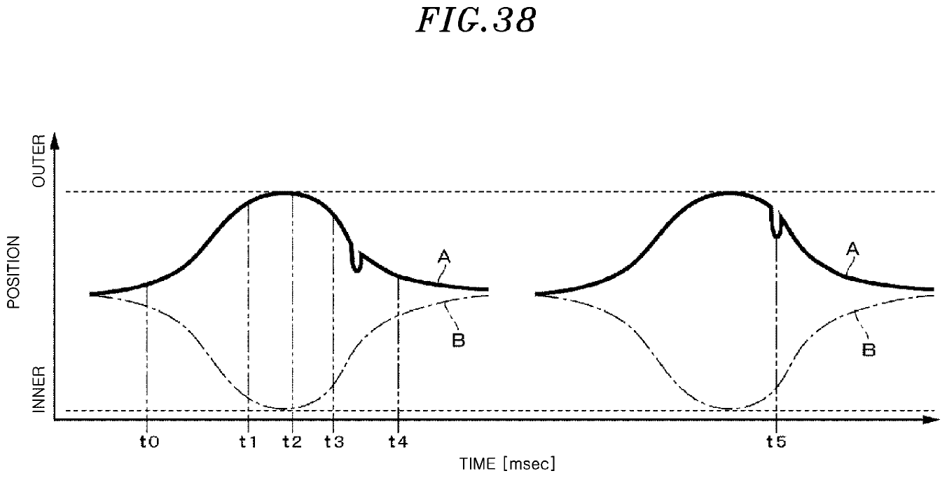

B. Test Results FIGS. 37 and 38 are graphs showing the results of Test 3. FIG. 37 shows an intensity profile of a single wavelength acquired at each position of the measurement area RB at time t1. In FIG. 37, the intensity range inside the two dashed lines is the intensity range used for the positioning and the film thickness inspection of the present disclosure. Each reflected light having an intensity falling within this intensity range can be determined to have been reflected from the substrate W and then incident on the HSC 11B, whereas reflected light having an intensity weaker than this intensity range is considered as light reflected outside the substrate W, for example, on the rotary table 72B. Further, it is clear that the boundary positions of the reflected lights with different intensities correspond to a black point A and a white point B on the peripheral edge of the substrate W shown in FIG. 36.

FIG. 38 is a graph showing temporal changes in the positions of points A and B in the measurement area RB, the points A and B on the peripheral edge of the substrate being identified using the correlation between the position and the intensity in the measurement area RB as shown in FIG. 37. Times t0 to t5 in FIG. 38 correspond to times t0 to t5 shown in FIG. 36. As shown in FIG. 38, the position where the solid line and the dash-dotted line indicating the positions of the points A and B intersect is a position where the substrate W first or last entered a position below the measurement area RB. The points A and B gradually move apart from this entry position, and it is considered that the diameter of the substrate W falls within the range under the measurement area RB at time t2 in which the points A and B are furthest apart. After time t2, the points A and B gradually approach each other to be located at the same position, and the period in which the points A and B are not detected is a period until the next substrate W reaches the measurement area RB. The period close to time t5 in which the point A is displaced from the inner side toward the outer side is a period in which the measurement area RB moved over a notch.

As shown in FIG. 38, the positions of the points A and B in the measurement area RB can be determined, and the position of the measurement area RB on the relatively revolving substrate W can be identified from time or temporal changes in the measurement range width in the measurement area RB: minimum width (first entry position)→maximum width (substrate diameter position)→minimum width (last entry position). Regarding the position in the measurement area RB where a certain acquired reflectance spectrum was measured, the position where the reflectance spectrum was measured can be determined by comparing it with data indicating the position of the peripheral edge of the substrate W as shown in FIG. 37. As described above, according to the in-line inspection shown in the modification of the fourth embodiment, it is possible to identify the measurement position of a certain reflectance spectrum acquired in the positioning of the inspection area T1 or in film thickness inspection.

The relative moving speed of the measurement area RB with respect to the substrate W as shown in FIG. 36 is low at the inner side of the measurement area RB and high at the outer side of the measurement area RB. To be strict, the displacement directions of these positions are not parallel to each other. Therefore, there are concerns that differences in the movement amount and the displacement direction between the inner side and the outer side of the measurement area RB may affect the reflectance spectra at respective positions, and may cause errors in positioning using the singular points of the present disclosure. In order to solve such problems, a separate test pattern was irregularly moved on the substrate W that revolves or moves linearly, and the spectroscopic measurement according to the fourth embodiment was performed under various conditions such as low resolution, high resolution, and with or without conversion to absolute value as shown in Test 3, and trends of singular points were confirmed. In such a test, similarly to Test 3, it was possible to identify singular points corresponding to the film thickness from the reflectance spectra obtained by measuring the test patterns. From this as well, it was confirmed that accurate positioning can be performed without errors even in the in-line inspection in the modification of the fourth embodiment.

It should be noted that the above-described embodiments are illustrative in all respects and are not restrictive. The above-described embodiments may be omitted, replaced, changed, or combined in various forms without departing from the scope of the appended claims and the gist thereof.

1. A method for inspecting a substrate by irradiating a substrate with light, comprising:
irradiating a measurement area set on the substrate with light and measuring a characteristic spectrum indicating characteristics of light absorption or reflection with respect to a wavelength of the light; and
determining an arrangement state of the substrate in the measurement area from a structure of the substrate identified by comparing an inspection target spectrum, which is the characteristic spectrum measured in said measuring the characteristic spectrum, with a reference spectrum, which is the characteristic spectrum obtained from a training model based on a film thickness or a substrate thickness identified from the substrate from which the inspection target spectrum was acquired, using the training model generated by learning the characteristic spectrum for multiple substrates in association with the film thickness when a film is formed on a surface of the substrate or a substrate thickness in a case where the characteristic spectrum changes according to the structure of the substrate in the measurement area.

2. The method of claim 1, wherein the characteristic spectrum is any one of an intensity spectrum, an absorption intensity spectrum, an absorbance spectrum, and a reflectance spectrum of reflected light from the measurement area.

3. The method of claim 1, wherein the light irradiated onto the measurement area is measurement light for performing spectroscopic measurement of a film on the surface of the substrate on which an uneven pattern, which is the structure of the substrate, is formed, and
in said determining the arrangement state of the substrate, whether the measurement area is located within an area where the uneven pattern is formed is determined from a comparison result between the inspection target spectrum obtained by identifying the film thickness and the reference spectrum, using the training model generated by learning the characteristic spectrum formed according to the uneven pattern in association with the film thickness of the film,
when it is determined in said determining the arrangement state that the measurement area is not located within the area where the uneven pattern is formed, moving the measurement area, said measuring the characteristic spectrum and said determining the arrangement state are repeated.

4. The method of claim 3, wherein the uneven pattern is formed in an inspection area where the spectroscopic measurement is performed.

5. The method of claim 4, wherein an adjacent area, where an uneven pattern different from the uneven pattern of the inspection area is formed, is provided adjacent to the inspection area of the substrate,
in said determining the arrangement state of the substrate, whether the measurement area is located within the inspection area or in the adjacent area is determined from a comparison result between the inspection target spectrum obtained by identifying the film thickness and the reference spectrum, using the training model generated by learning the characteristic spectrum formed according to the uneven patterns of the inspection area and the adjacent area, and
when it is determined in said determining the arrangement state that the measurement area is located within the adjacent area, in said moving the measurement area, the measurement area is moved based on a direction and a movement distance preset based on an arrangement relationship between the inspection area and the adjacent area.

6. The method of claim 3, wherein the uneven pattern is an alignment mark provided to perform alignment adjustment of the substrate and formed in a preset area in the surface of the substrate.

7. The method of claim 3, wherein, a singular point is defined as a wavelength of the light at a position where multiple types of the characteristic spectra obtained by changing the structure of the substrate intersect, or a wavelength of the light at a position where a difference between values of the multiple types of the characteristic spectra becomes minimum when the multiple types of the characteristic spectra do not intersect,
the method further comprising identifying values at the singular points of the inspection target spectrum and the reference spectrum after said measuring the characteristic spectrum, and
said determining the arrangement state of the substrate is not executed when a difference between the value identified in the inspection target spectrum and the value identified in the reference spectrum is greater than or equal to a preset tolerance.

8. The method of claim 7, wherein the singular point changes according to the film thickness of the film on the surface of the substrate, and
in said identifying values at the singular points, the values at the singular points corresponding to the film thickness are identified.

9. The method of claim 1, wherein the substrate is a bonded substrate formed by bonding a first substrate and a second substrate, and the light irradiated onto the measurement area is infrared light for performing measurement of an internal structure of the bonded substrate, and
in said determining the arrangement state of the substrate, whether the first substrate and the second substrate are bonded at an accurate position is determined based on a comparison result between the inspection target spectrum obtained by identifying the thickness of the substrate and the reference spectrum, using the training model generated by learning the characteristic spectrum formed according to a bonding state between the first substrate and the second substrate in association with the thickness of the bonded substrate.

10. The method of claim 9, wherein the bonding state is misalignment of metal pads that are respectively provided on the first substrate and the second substrate to connect the first substrate and the second substrate to each other.

11. The method of claim 1, wherein in said measuring the characteristic spectrum, the characteristic spectrum is measured by a hyperspectral camera.

12. The method of claim 11, wherein a measurement area of the characteristic spectrum by the hyperspectral camera is configured in an elongated rectangular shape having a longitudinal dimension greater than a diameter of the substrate, and
in the measurement using the hyperspectral camera, the measurement area scans an entire surface of the substrate by relatively moving the measurement area in a fixed direction with respect to multiple substrates placed on a stage.

13. An apparatus for inspecting a substrate, comprising:
a stage;
an inspection part configured to irradiate a measurement area set on the substrate placed on the stage with light and receive reflected light; and
a control part;
wherein the control part outputs a control signal for executing:
measuring a characteristic spectrum indicating characteristics of light absorption or reflection with respect to a wavelength of the light, by irradiating a measurement area set on the substrate with light; and
determining an arrangement state of the substrate in the measurement area from a structure of the substrate identified by comparing an inspection target spectrum, which is the characteristic spectrum measured in said measuring the characteristic spectrum, with a reference spectrum, which is the characteristic spectrum obtained from a training model based on a film thickness or a substrate thickness identified from the substrate from which the inspection target spectrum was acquired, using the training model generated by learning the characteristic spectrum for multiple substrates in association with the film thickness when a film is formed on a surface of the substrate or a substrate thickness in a case where the characteristic spectrum changes according to the structure of the substrate in the measurement area.

14. The apparatus of claim 13, wherein the characteristic spectrum is any one of an intensity spectrum, an absorption intensity spectrum, an absorbance spectrum, and a reflectance spectrum of reflected light from the measurement area.

15. The apparatus of claim 13, wherein the inspection part is configured to move the measurement area, and the light irradiated onto the measurement area is measurement light for performing spectroscopic measurement of a film on the surface of the substrate on which an uneven pattern, which is the structure of the substrate, is formed, and
in said determining the arrangement state of the substrate, the control part determines whether the measurement area is located within an area where the uneven pattern is formed from a comparison result between the inspection target spectrum obtained by identifying the film thickness and the reference spectrum, using the training model generated by learning the characteristic spectrum formed according to the uneven pattern in association with the film thickness of the film,
when it is determined in said determining the arrangement state that the measurement area is not located within the area where the uneven pattern is formed, the control part outputs a control signal for repeatedly executing moving the measurement area, said measuring the characteristic spectrum and said determining the arrangement state.

16. The apparatus of claim 15, wherein the uneven pattern is formed in an inspection area where the spectroscopic measurement is performed.

17. The apparatus of claim 16, wherein an adjacent area, where an uneven pattern different from the uneven pattern of the inspection area is formed, is provided adjacent to the inspection area of the substrate, and
in said determining the arrangement state of the substrate, the control part determines whether the measurement area is located within the inspection area or in the adjacent area from a comparison result between the inspection target spectrum obtained by identifying the film thickness and the reference spectrum, using the training model generated by learning the characteristic spectrum formed according to the uneven pattern of the inspection area and the adjacent area, and
when it is determined in said determining the arrangement state that the measurement area is located within the adjacent area, the control part outputs a control signal for moving the measurement area based on a direction and a movement distance preset based on an arrangement relationship between the inspection area and the adjacent area in said moving the measurement area.

18. The apparatus of claim 15, wherein the uneven pattern is an alignment mark provided to perform alignment adjustment of the substrate and formed in a preset area in the surface of the substrate.

19. The apparatus of claim 15, wherein, a singular point is defined as a wavelength of the light at a position where multiple types of the characteristic spectra obtained by changing the structure of the substrate intersect, or a wavelength of the light at a position where a difference between values of the multiple types of the characteristic spectra becomes minimum when the multiple types of the characteristic spectra do not intersect,
the control part outputs a control signal to identify values at the singular points of the inspection target spectrum and the reference spectrum after said measuring the characteristic spectrum, and to prevent execution of said determining the arrangement state of the substrate when a difference between the value identified in the inspection target spectrum and the value identified in the reference spectrum is greater than or equal to a preset tolerance.

20. The apparatus of claim 19, wherein the singular point changes according to the film thickness of the film on the surface of the substrate, and
in said identifying values at the singular points, the control part outputs a control signal for identifying the values at the singular points corresponding to the film thickness.

21. The apparatus of claim 13, wherein the substrate is a bonded substrate formed by bonding a first substrate and a second substrate, and the light irradiated onto the measurement area is infrared light for performing measurement of an internal structure of the bonded substrate, and
in said determining the arrangement state of the substrate, the control part outputs a control signal for determining whether the first substrate and the second substrate are bonded at an accurate position, based on a comparison result between the inspection target spectrum obtained by identifying the thickness of the substrate and the reference spectrum, using the training model generated by learning the characteristic spectrum formed according to a bonding state between the first substrate and the second substrate in association with the thickness of the bonded substrate.

22. The apparatus of claim 21, wherein the bonding state is misalignment of metal pads that are respectively provided on the first substrate and the second substrate to connect the first substrate and the second substrate to each other.

23. The apparatus of claim 13, wherein the inspection part includes a hyperspectral camera configured to measure the inspection target spectrum.

24. The apparatus of claim 23, wherein a measurement area of the hyperspectral camera is configured in an elongated rectangular shape having a longitudinal dimension greater than the diameter of the substrate, and
the measurement area scans an entire surface of the substrate by relatively moving the measurement area in a fixed direction with respect to multiple substrates placed on the stage.

25. A substrate processing apparatus comprising:
the apparatus described in claim 24;
a rotation axis that rotates the stage;
a processing chamber accommodating the stage on which the multiple substrates are placed and revolve around the rotation axis; and
a processing gas supply part configured to supply a processing gas to the substrate,
wherein the substrate is inspected after processing is performed by supplying the processing gas to the substrate placed on the stage.
